(19) United States
(12) Patent Application Publication
(10) Pub. No.: US 2024/0282888 A1
(43) Pub. Date: Aug. 22, 2024

(54) MICRO-LED WITH IMPROVED LIGHT EXTRACTION

(71) Applicant: Google LLC, Mountain View, CA (US)

(72) Inventor: Aurelien Jean Francois David, San Francisco, CA (US)

(21) Appl. No.: 18/571,080

(22) PCT Filed: Jun. 10, 2022
(86) PCT No.: PCT/US2022/032986

§ 371 Date: Dec. 15, 2023

Related U.S. Application Data
(60) Provisional application No. 63/211,168, filed on Jun. 16, 2021.

(51) Int. Cl. H01L 33/20; H01L 27/15; H01L 33/46

(52) U.S. Cl. CPC H01L 33/20; H01L 27/15; H01L 33/46

(57) ABSTRACT

A micro light-emitting diode, micro-LED, is configured to provide increased light-extraction. The micro-LED (300) according to the present disclosure has a lateral dimension less than 20 micrometres and comprises: a light-emitting layer (106), an output facet (308), an optical interface (via a mirror 114) parallel to the light-emitting layer, and a non-vertical sidewall (102) forming an angle with respect to a normal of the light-emitting layer. The layer (106) emits light (310) comprising a first light (312) in a first trajectory that escapes the micro-LED through the output facet (308) without reflecting off the optical interface and a second light (314) in a second trajectory that reflects off the optical interface and the non-vertical sidewall (102) and escapes through the output facet. The disclosed micro-LEDs may further include one or more of: cavity effects, light guiding, total internal reflection at low-index layers, mirrors, and micro-optics.

### BACKGROUND

A display panel includes an array of pixels arranged in rows and columns, typically having on the order of thousands or even tens-of-thousands of rows and columns. Each pixel may be implemented as a matrix of sub-pixels, such as a particular arrangement of red, green, and blue (RGB) sub-pixels, each of which is controlled to emit light of the corresponding color at a corresponding luminance, and the combination of light colors and their luminance results in the intended brightness and color for the pixel as a whole. Light emitting diode (LED) displays include an array of LEDs forming the sub-pixels. Future displays are expected to include micro-LEDs composed of a semiconductor and other materials known in the art with pixels having a lateral dimension that is smaller than 50 μm. However, light emitted by a micro-LED can become trapped due to the refractive index difference between the semiconductor and the outside world.

### SUMMARY OF EMBODIMENTS

One aspect of the proposed solution relates to a micro light emitting diode (micro-LED) device comprising a lateral dimension less than 20 microns, comprising a light-emitting layer; an output facet; an optical interface parallel to the light-emitting layer; and a non-vertical sidewall forming an angle γ with respect to a normal of the light-emitting layer, wherein the light-emitting layer emits light comprising a first light in a first trajectory that escapes the micro-LED through the output facet without substantially reflecting off the optical interface and a second light in a second trajectory that reflects off the optical interface and the non-vertical sidewall and escapes through the output facet.

In an example embodiment of the micro-LED device, the optical interface is an interface between a high-index semiconductor and a low-index semiconductor.

Additionally or alternatively, the second light comprises at least 10% of the light emitted by the light emitting layer; the angle γ is selected to reflect the second light in a direction substantially perpendicular to the output facet; at least 50% of an optical power emitted in the second light escapes through the output facet; and the second light reflects off the optical interface through a total internal reflection.

The proposed solution further relates to a method comprising selecting an angle γ of a non-vertical sidewall with respect to a normal of a light-emitting layer of a micro light emitting diode (micro-LED), the micro-LED comprising a layer having an optical thickness d between the light-emitting layer and a mirror, to direct a first light emitted by the light-emitting layer along a first trajectory that reflects off the non-vertical sidewall and through an output facet of the micro-LED.

In an example embodiment, the method further comprises selecting the angle γ to direct a second light emitted by the light-emitting layer along a second trajectory that reflects off the mirror and the non-vertical sidewall and through the output facet of the micro-LED. The method may also include selecting the angle γ to reflect the second light in a direction substantially perpendicular to the output facet. In an example embodiment, at least 50% of an optical power emitted in the second light escapes through the output facet.

The proposed solution further relates to a micro-LED device having a lateral dimension less than 20 um, comprising: a light emitting layer to emit light having a wavelength; an output facet; a mirror parallel to the light emitting layer and in optical proximity to the light emitting layer; and a non-vertical sidewall, wherein the light emitting layer and the mirror are jointly configured such that the light emitting layer preferentially emits light in a trajectory that reflects off the mirror and the non-vertical sidewall to escape through the output facet.

In an example embodiment, a distance between the mirror and the light emitting layer is less than three times the wavelength. Additionally or alternatively, a distance between the mirror and the light emitting layer is selected to cause a constructive optical interference for the light emitted in the trajectory; at least 10% of a total emission by the light emitting layer is emitted in the trajectory; the light emitted in the trajectory has an enhancement factor of at least 2.5 compared to a light that would be emitted by the light emitting layer in a homogeneous material; and the light emitting layer emits a second light in a second trajectory that is not substantially extracted from the micro-LED, with an enhancement factor less than 0.5.

The proposed solution further relates to a display, comprising: a semiconductor member having a display output surface to emit a display light in a vertical direction; and a plurality of micro-light emitting diodes (micro-LEDs) formed epitaxially on the semiconductor member, at least one micro-LED comprising: non-vertical sidewalls; a light-emitting layer; a mirror formed on a facet of the micro-LED opposite the semiconductor member; and a low-index epitaxial layer located in the micro-LED or in the semiconductor member, wherein the low-index epitaxial layer and the mirror are configured such that a light emitted by the light-emitting layer reflects at least once off the low-index epitaxial layer and once off the mirror before being emitted through the output surface.

In an example embodiment, the light is emitted by the light-emitting layer at an angle greater than 60 degrees with respect to a normal of the output surface. Additionally or alternatively, a difference between a first index of refraction of the low-index epitaxial layer and a second index of refraction of the semiconductor member is at least 0.2; the reflection off the low-index epitaxial layer is a total internal reflection; the light further reflects off one of the non-vertical sidewalls before being emitted through the output surface; at least 50% of the light emitted by the light-emitting layer is extracted from the LED; the low-index epitaxial layer is AlInN; the low-index epitaxial layer has an index less than 2.4, at a wavelength of emission of the light-emitting layer; the light impinges on the low-index epitaxial layer from a layer that is either GaN or InGaN; and at least 20% of light emitted by the light-emitting layer is emitted as a total internal reflection (TIR) light, wherein the TIR light is emitted at angles that undergo TIR on the low-index epitaxial layer.

The proposed solution further relates to a display, comprising: a semiconductor member having a display output surface to emit a display light in a substantially vertical direction; a plurality of micro-light emitting diodes (micro-LEDs) formed epitaxially on the semiconductor member, at least one micro-LED comprising: a light-emitting region; a mirror formed on a facet of the micro-LED opposite the semiconductor member; and a low-index epitaxial layer located in the micro-LED or in the semiconductor member, wherein the low-index epitaxial layer and the mirror are configured such that at least 5% of the light emitted by the light-emitting region undergoes one reflection off the mirror and one total internal reflection off the low-index epitaxial layer before being extracted from the display.

In an example embodiment, the at least one micro-LED further comprises non-vertical sidewalls.

The proposed solution further relates to a display, comprising: a semiconductor member with a first side comprising a micro-light emitting diode (micro-LED) mesa and a second side opposite the first side comprising a secondary micro-optic, wherein the micro-LED mesa comprises a non-vertical sidewall and a light-emitting layer configured to emit an emitted light, wherein at least 10% of the emitted light is in a trajectory which impinges on the non-vertical sidewall and then on the secondary micro-optic, and the non-vertical sidewall and the secondary micro-optic are configured such that light emitted in the trajectory is extracted from the display.

In some embodiments, the display further comprises an optical isolation structure configured to prevent the emitted light from propagating laterally across the display. In some embodiments, the optical isolation structure of the display is configured such that less than 10% of the emitted light travels laterally more than 10 um from the micro-LED mesa. Additionally or alternatively, in some embodiments, the optical isolation structure is configured such that less than 5% of the emitted light is extracted from the display at a lateral distance more than 10 um from the micro-LED mesa. In some embodiments, the mesa comprises a mirror in optical proximity to the light-emitting layer, and the mirror and the light-emitting layer are separated by an optical distance based on a predetermined direction corresponding to the trajectory.

The proposed solution further relates to a method of designing a display comprising a planar member, a micro-mesa formed on the planar member, a light-emitting layer and a mirror in optical proximity to the light-emitting layer, and a secondary micro-optic optically coupled to the planar member, comprising: providing a wave-optics model to compute an emission diagram caused by optical interference between the mirror and the light-emitting layer; providing a geometric-optics model to compute an optical interaction between the emission diagram and the secondary micro-optic; and jointly configuring the geometries of the micro-mesa and of the secondary micro-optic based on the wave-optics model and to the geometric-optics model, to yield a predetermined light extraction efficiency from the display.

The proposed solution further relates to a display comprising: a semiconductor member having a display output surface to emit a display light in a vertical direction; a plurality of micro-light emitting diodes (micro-LEDs) formed epitaxially on the semiconductor member, at least one micro-LED comprising: non-vertical sidewalls; a light-emitting layer, emitting light at an emission wavelength; and a plurality of surrounding layers in a vicinity of the light-emitting layer, wherein: the light-emitting layer and the surrounding layers have a refractive index and a thickness to carry a guided mode at the emission wavelength, in a direction perpendicular to the vertical direction; upon operation of the at least one micro-LED, at least 10% of the light emitted by the light-emitting layer is a guided light emitted in the guided mode; and the non-vertical sidewalls are configured to extract at least 50% of the guided light through the output surface.

In some embodiments, the light-emitting layer and surrounding layers form a waveguide with a thickness more than 20 nm and less than 1 um. Additionally or alternatively, the non-vertical sidewalls redirect the guided light in a direction that is not perpendicular to the vertical direction.

The proposed solution further relates to a method of operating a micro light emitting diode (micro-LED) display, comprising: providing a display having a semiconductor member, the member having an output surface from which a display light is emitted and a plurality of micro-LED pixels separated by a pitch distance P, each micro-LED pixel comprising non-vertical sidewalls; and injecting an electrical current to at least one pixel, such that an LED light is emitted inside the injected pixel, wherein the non-vertical sidewalls are configured to form an angle with a normal of a light-emitting surface of the micro-LED pixels to direct at least 20% of the LED light as an extracted light that is extracted from the micro-LED pixels through the output surface; and at least 50% of the extracted light is extracted within a predetermined vicinity of the injected pixel.

In some embodiments, the predetermined vicinity corresponds to a lateral region that is less than five times the pitch distance P from a center of the injected pixel.

The proposed solution further relates to a method of operating a micro light emitting diode (micro-LED) display, comprising: providing a display having a semiconductor member, the member having an output surface from which a display light is emitted and a plurality of micro-LED pixels separated by a pitch distance P, each micro-LED pixel comprising an optical isolation structure; and injecting an electrical current to at least one pixel, such that an LED light is emitted inside the injected pixel, wherein the optical isolation structures are configured such that less than less than 10% of the LED light travels away from a predetermined vicinity of the at least one pixel.

In some embodiments, the optical isolation structures are further configured such that at least 20% of the LED light escapes through the output surface. Additionally or alternatively, the micro-LED pixels comprise non-vertical sidewalls, which are configured such that at least 20% of the LED light escapes through the output surface.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a diagram of a micro light-emitting diode (micro-LED) having slanted sidewalls in accordance with some embodiments.

FIG. 2 is a graph illustrating emission of a quantum well as a function of the optical thickness of a layer between an active region and a bottom mirror of a micro-LED in accordance with some embodiments.

FIG. 3 is a diagram of a light trajectory from a micro-LED having slanted sidewalls in accordance with some embodiments.

FIG. 4 is a graph of light extraction from a micro-LED based on the angle of slanted sidewalls and the optical thickness of a layer between the active region and the bottom mirror of the micro-LED in accordance with some embodiments.

FIG. 5 is a graph of light extraction from a micro-LED based on the angle of slanted sidewalls and the optical thickness of a layer between the active region and the bottom mirror of the micro-LED in accordance with some embodiments.

FIG. 6 is a graph of light extraction from a micro-LED with slanted sidewalls in accordance with some embodiments.

FIG. 7 is a graph of light extraction from a micro-LED with slanted sidewalls in accordance with some embodiments.

FIG. 8 is a diagram of a light trajectory from a display with an array of multiple micro-LEDs with slanted sidewalls in accordance with some embodiments.

FIG. 9 is a diagram of light trajectories from a micro-LED with slanted sidewalls in accordance with some embodiments.

FIG. 10 is a diagram of light trajectories from a micro-LED with slanted sidewalls and a low-index layer in accordance with some embodiments.

FIG. 11 is a diagram of light trajectories from a display with an array of multiple micro-LEDs with slanted sidewalls and a low-index layer in accordance with some embodiments.

FIG. 12 is a diagram of light trajectories from a display with an array of multiple micro-LEDs with slanted sidewalls, a low-index layer, optical isolation features, and secondary optical features in accordance with some embodiments.

FIG. 13 is a diagram of light trajectories from a display with an array of multiple micro-LEDs with slanted sidewalls, a low-index layer, optical isolation features, and periodic or quasi-periodic secondary optical features in accordance with some embodiments.

FIG. 14 is a diagram of a display with an array of multiple micro-LEDs with slanted sidewalls, a low-index layer, optical isolation features, and a secondary optical feature that is a random surface in accordance with some embodiments.

FIG. 15 is a diagram of a sub-pixel micro-LED with slanted sidewalls and secondary extraction features in accordance with some embodiments.

FIG. 16 is a diagram of a sub-pixel micro-LED with slanted sidewalls and secondary extraction features in accordance with some embodiments.

FIG. 17 is a diagram of a sub-pixel micro-LED with slanted sidewalls and secondary extraction features in accordance with some embodiments.

FIG. 18 is a diagram of a sub-pixel micro-LED with slanted sidewalls and secondary extraction features in accordance with some embodiments.

FIG. 19 is a diagram of a sub-pixel micro-LED with slanted sidewalls and secondary extraction features in accordance with some embodiments.

FIG. 20 is a source emission diagram of a sub-pixel micro-LED with slanted sidewalls and secondary extraction features in accordance with some embodiments.

FIG. 21 is a source emission diagram in which light emission is enhanced in some directions light emission is inhibited in some directions in accordance with some embodiments.

FIG. 22 is a diagram illustrating the formation of isolation features for a micro-LED in accordance with some embodiments.

FIG. 23 is a diagram illustrating a light trajectory with respect to a low-index layer in accordance with some embodiments.

FIG. 24 is a graph illustrating the reflectivity R of a low-index layer as a function of an angle of incidence theta in accordance with some embodiments.

FIG. 25 is a graph illustrating the reflectivity of a low-index layer as a function of the index contrast between the semiconductor and the low-index layer in accordance with some embodiments.

FIG. 26 is a graph illustrating the light extraction from a micro-LED without a low-index layer in accordance with some embodiments.

FIG. 27 is a graph illustrating the light extraction from a micro-LED without a low-index layer in accordance with some embodiments.

FIG. 28 is a graph illustrating the light extraction from a micro-LED with a low-index layer in accordance with some embodiments.

FIG. 29 is a graph illustrating the light extraction from a micro-LED with a low-index layer in accordance with some embodiments.

FIG. 30 is a graph illustrating light extraction into air as a function of angle for a micro-LED in accordance with some embodiments.

FIG. 31 is a graph illustrating light extraction into air as a function of angle for a micro-LED in accordance with some embodiments.

FIG. 32 is a graph illustrating light extraction as a function of pixel size of a micro-LED in accordance with some embodiments.

FIG. 33 is graph illustrating light extraction as a function of mirror reflectivity of a micro-LED in accordance with some embodiments.

FIG. 34 is a block diagram of a mirror architecture for a micro-LED in accordance with some embodiments.

FIG. 35 is a block diagram of a mirror architecture for a micro-LED in accordance with some embodiments.

FIG. 36 is a block diagram of a mirror architecture for a micro-LED in accordance with some embodiments.

FIG. 37 is a block diagram of a mirror architecture for a micro-LED in accordance with some embodiments.

FIG. 38 is a block diagram of a cavity geometry of a micro-LED in accordance with some embodiments.

FIG. 39 is an emission diagram comparing a half-cavity without a low-index layer and a full cavity with a low-index layer in accordance with some embodiments.

FIG. 40 is an emission diagram comparing a half-cavity without a low-index layer and a full cavity with a low-index layer in accordance with some embodiments.

FIG. 41 is a graph illustrating light extraction light under various cavity parameters of a micro-LED in accordance with some embodiments.

FIG. 42 is a graph illustrating light extraction light under various cavity parameters of a micro-LED in accordance with some embodiments.

FIG. 43 is a graph illustrating a Purcell factor of a micro-LED in accordance with some embodiments.

FIG. 44 is a block diagram of a geometry for a micro-LED mesa in accordance with some embodiments.

FIG. 45 is a block diagram of a geometry for a micro-LED mesa in accordance with some embodiments.

FIG. 46 is a block diagram of a geometry for a micro-LED mesa in accordance with some embodiments.

FIG. 47 is an isometric view of multiple subpixels of a micro-LED array having slanted sidewalls in accordance with some embodiments.

FIG. 48 is a top view of multiple subpixels of a micro-LED array having slanted sidewalls in accordance with some embodiments.

FIG. 49 is block diagram of a semiconductor stack of a micro-LED in accordance with some embodiments.

FIG. 50 illustrates a fabrication flow for a micro-LED in accordance with some embodiments.

FIG. 51 is a block diagram illustrating layers around a micro-LED mesa in accordance with some embodiments.

FIG. 52 is a block diagram illustrating layers around a micro-LED mesa in accordance with some embodiments.

FIG. 53 is a block diagram of an epitaxial structure of a micro-LED in accordance with some embodiments.

FIG. 54 is a block diagram of an epitaxial structure of a micro-LED in accordance with some embodiments.

### DETAILED DESCRIPTION

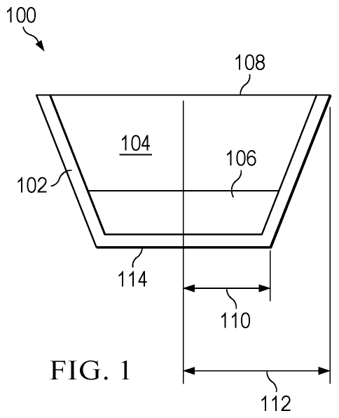

A micro-LED has lateral dimensions less than 20 um (or 10 um, 5 um, 3 um, 2 um, 1.5 um, 1 um). Conventional micro-LEDs, with cubic shapes, lead to low light extraction, as most of the light remains trapped in the semiconductor material. FIGS. 1-54 illustrate techniques for enhancing extraction of light from micro-LEDs through one or more of mirror interference and non-vertical sidewalls, optical isolation features to prevent light emitted by one pixel of a pixel array from escaping above another pixel of the pixel array, incorporation of a low-index epitaxial layer (also referred to herein as a low-index layer or LIL) to reflect light emitted at large angles, secondary micro-optics, and a guided mode in which an active layer of the micro-LED is surrounded by high-index layers, creating a waveguide to direct emitted light to a specific point on a sidewall of the micro-LED.

A micro-LED includes a bottom mirror and mirrored sidewalls. A light-emitting layer (also referred to herein as an active region) sits above the bottom mirror and a semiconductor layer rests above the active region. By varying an optical thickness d of the layer between the active region and the bottom mirror, the direction in which light is emitted from the active region changes. In some embodiments, the mirrored sidewalls are tilted at a non-vertical angle γ with respect to normal from the active region such that light emitted at an angle based on the optical thickness d of the layer between the active region and the bottom mirror reflects off one or more of the mirrored sidewalls to escape the micro-LED. By adjusting the non-vertical angle γ to extract light emitted from the micro-LED at directions predicted based on the optical thickness d, the configuration of the micro-LED extracts more light than would be extracted from a micro-LED having vertical sidewalls.

In some embodiments, an array of micro-LEDs includes optical isolation features between micro-LED pixels to prevent light emitted by one micro-LED of the array from escaping above another micro-LED of the array. The optical isolation features are made of reflecting or absorbing material in some embodiments.

In some embodiments, a low-index layer is added to the micro-LED between the active region and the semiconductor layer. The low-index layer selectively transmits light emitted at relatively small angles with respect to normal and selectively reflects light emitted at relatively large angles with respect to normal from the active region. The reflected light experiences a secondary trajectory in which the light reflects off one or more of the non-vertical slanted sidewalls of the micro-LED before impinging on the low-index layer at a small angle with respect to normal. When the light impinges on the low-index layer at a relatively small angle following the secondary trajectory, the low-index layer transmits the light out of the micro-LED at the relatively small angle. Thus, the low-index layer enhances light extraction from the micro-LED and further enhances light extraction from the micro-LED that is localized to the vicinity of the micro-LED rather than being emitted at large angles with respect to normal.

In some embodiments, each micro-LED of an array of micro-LEDs includes secondary micro-optics to increase the light extraction and the directionality of the emission from the micro-LED. The geometry of the secondary micro-optics is selected based on a desired effect on the light emitted from the micro-LEDs.

The active layer of the micro-LED is surrounded by high-index layers in some embodiments, creating a waveguide to direct emitted light to a specific point on a sidewall of the micro-LED in what is referred to herein as a “guided mode”. Light in a guided mode travels laterally and is extracted by the slanted sidewall upon reaching the mesa edge.

Some embodiments described herein incorporate one or more of the aforementioned features. For example, in some embodiments, a micro-LED incorporates non-vertical sidewalls and a low-index layer. In other example, a micro-LED array includes micro-LEDs having one or more of non-vertical sidewalls, a low-index layer, optical isolation features, and secondary micro-optics. These features in combination synergistically extract more light from each micro-LED of an array and direct the extracted light

### Mirror Interference and Non-Vertical Sidewall

FIG. 1 illustrates a micro light-emitting diode (micro-LED) 100 having slanted sidewalls 102 in accordance with some embodiments. In some embodiments, the micro-LED 100 has the shape of a truncated cone, while in other embodiments the micro-LED 100 includes a number of facets (e.g., 3, 4, 5, 6 facets or more). The micro-LED 100 is composed of a semiconductor, such as a III-V compound, a III-Nitride compound, an AlInGaN compound, an AlInGaAsP compound, and other materials known in the art. The micro-LED 100 has a light-emitting active region 106 (also referred to herein as a light-emitting region or an active region), such as at least one InGaN quantum well (QW). The bottom of the micro-LED 100 is covered with a bottom mirror 114 that acts as an optical interface and the sidewalls 102 are also covered with a mirror. In some embodiments, the mirror has a reflectivity R=85%, which corresponds, for example, to an Al mirror formed on GaN.

By configuring the shape of the micro-LED and the thickness of epitaxial layers, light extraction is improved. In particular, the optical thickness d of the layer between the active region 106 and the bottom 114 mirror can give rise to cavity effects due to interference. Although FIG. 1 shows a planar active region 106, non-planar active regions are also possible. In some embodiments, the active region 106 may have a planar region and a slanted region—for instance, if it is grown on a mesa having slanted sidewalls and conformal growth of the active region occurs.

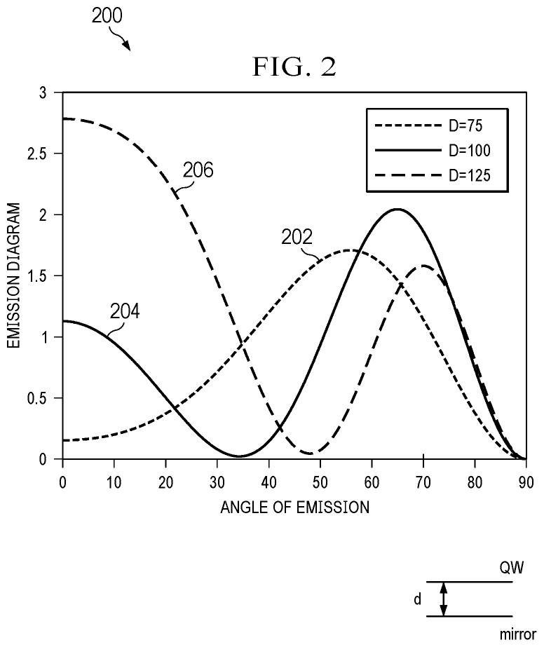

FIG. 2 illustrates an emission diagram 200 of a quantum well as a function of the optical thickness d of a layer between the active region 106 and the bottom mirror 114 of the micro-LED 100 in accordance with some embodiments. The emission diagram 200 (i.e., intensity vs. angle) of the quantum well is affected by the value of d using a wave-optic model. In the illustrated example, the bottom mirror 114 is an Al mirror formed on a GaN matrix (refractive index n=2.4). For the curve 202, in which d=75 nm, interference gives rise to a lobe around 50 deg. For the curve 204, in which d=100 nm, the diagram has one lobe near normal incidence and a lobe around 65 deg. For the curve 206, in which d=125 nm, the diagram has one intense lobe near normal incidence and a lobe around 65 deg. Thus, for a smaller (thinner) optical thickness d of the layer between the active region 106 and the bottom mirror 114, only one lobe of emission is present, whereas for a greater (thicker) optical thickness d, multiple lobes of emission are present. By controlling the optical thickness d, the micro-LED 100 is configured to select for one or more preferred angles of emission.

In addition to controlling the optical thickness d, aspects of the micro-LED 100 such as the refractive index of the materials and the index of the reflector are configured so that light can be emitted in desired directions. By jointly configuring the shape (e.g., the slant angle of the non-vertical sidewalls 102 and/or a curvature of the non-vertical sidewalls 102) of the micro-LED 100, light emitted in the desired directions can be extracted. Such interference-based modification of the angular emission diagram exceeds what a distant mirror would achieve (i.e., if wave optic effects do not matter) and can be quantified by an enhancement factor.

The enhancement factor is defined as the ratio of power emitted by the active region 106 in a given direction in an embodiment, divided by the power that the active region would emit in the same direction in a bulk semiconductor (i.e., an infinite homogeneous semiconductor without optical interfaces). If a distant mirror has a reflection coefficient r and reflectivity R (with R=|r\hat{ }2|), the distant mirror can enhance emission in a direction by (1+R), which is always more than 1 and less than 2. In contrast, interferences can enhance the emission by a factor |1+r|\hat{ }2, which can be as high as 4 (for a lossless mirror) and as low as zero. Accordingly, some embodiments of the micro-LED 100 experience an enhancement factor higher than 2 (or 2.5 or 3) in a direction. Some embodiments of the micro-LED 100 are characterized by an enhancement factor less than 0.5 (or 0.2, 0.1) in a direction. In the case of FIG. 2, the enhancement factor can be higher than 2.5 and less than 0.1. (a mirror with a higher reflectivity than Al would lead to even higher enhancement factor).

Some embodiments of the micro-LED 100 have a large enhancement factor in a first direction, where light is well extracted, and have a small enhancement factor in a second direction, where light is less well extracted. In some embodiments, the micro-LED 100 is configured such that a direction has a light extraction higher than 30% (or 50%, 70%) and has an enhancement factor higher than 2 (or 2.5, 3). In some embodiments, the micro-LED 100 is configured such that a direction has a light extraction less than 30% (or 20%, 10%) and has an enhancement factor less than 0.5 (or 0.2, 0.1).

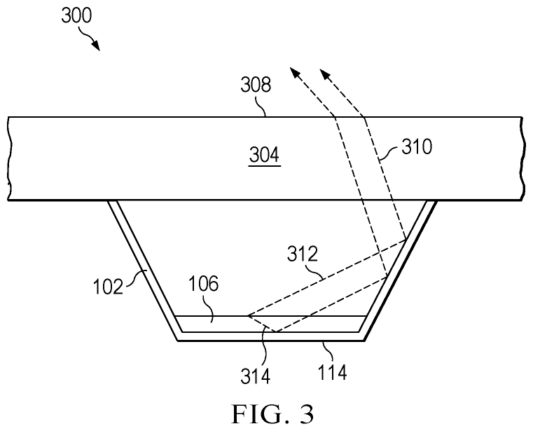

FIG. 3 is a diagram of a light 310 trajectory with enhanced light extraction from a micro-LED 300 having slanted sidewalls 102 in accordance with some embodiments. The micro-LED 300 includes a bottom mirror 114 and an active region 106 as well as a semiconductor layer 304 with an output facet 308.

Light 310 is emitted from the active region 106 of the micro-LED 300 in two directions: upward in a first light trajectory 312 and downward at an angle in a second light trajectory 314. The light emitted downward in the second light trajectory 314 is reflected by the bottom mirror 114 of the micro-LED 300. The two sub-beams of the first light trajectory 312 and the second light trajectory 314 cause an interference that enhances light emission at the angle. The light of the first light trajectory 312 and the second light trajectory 314 is then reflected by the non-vertical sidewall 102 and is extracted through the output facet 308 of the semiconductor layer 304.

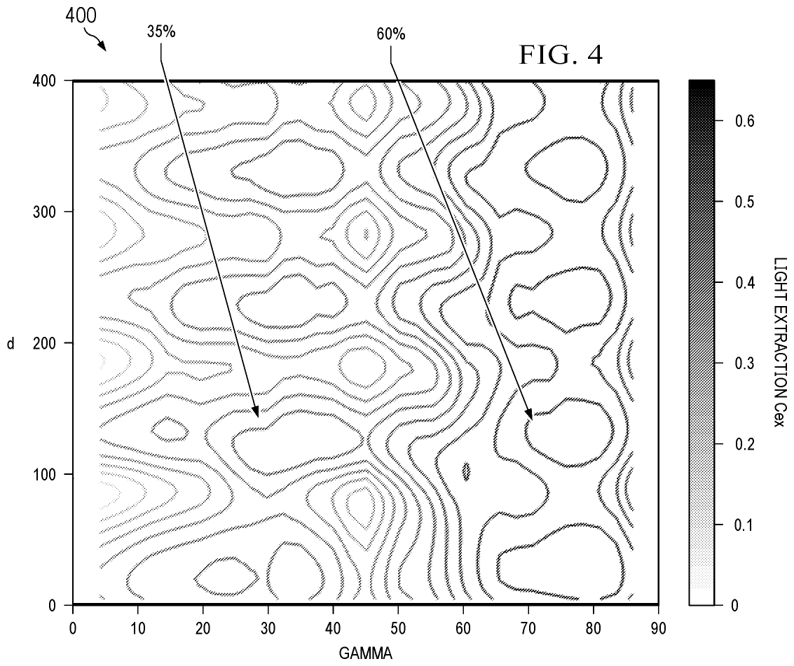

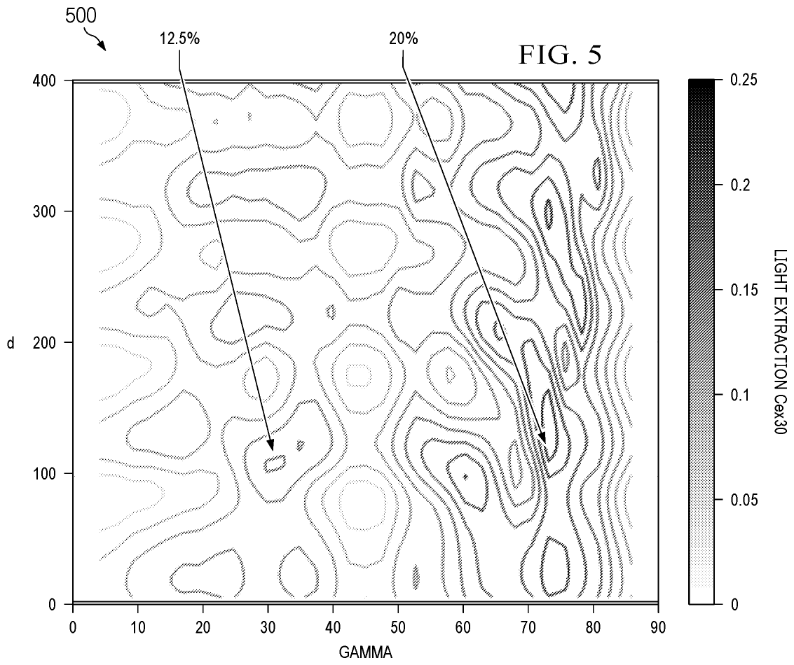

FIGS. 4 and 5 are graphs 400, 500 of light extraction from the micro-LED 100 based on the angle of slanted sidewalls 102 and the optical thickness d of a layer between the active region 106 and the bottom mirror 114 of the micro-LED 100 in accordance with some embodiments. The graph 400 of FIG. 4 illustrates the results of a model where the optical thickness d and the shape of the micro-LED 100 are varied. The shape of the micro-LED 100 is controlled by the angle gamma of the non-vertical sidewall 102 (with gamma=0 corresponding to a vertical sidewall). In the illustrated example, the base radius of the micro-LED 100 is 1.5 um, and the bottom mirror 114 and the mirror on the non-vertical sidewall 102 have a reflectivity Rp=85%. The amount of light extraction is computed by combining a wave-optic model (to account for interference effects) with a geometric-optics (raytracing) model, to describe propagation of the light in the micro-LED 100. The graph 400 of FIG. 4 illustrates the total light extraction (Cex).

FIG. 5 is a graph 500 illustrating the light extraction from the micro-LED 100 in a 30 deg cone (Cex30). For some values of gamma and d, Cex and Cex30 reach high values. For instance, in the region d=120-130 nm and gamma ˜35 deg, Cex reaches 35% and Cex30 reaches 12.5%. In some embodiments, the micro-LED 100 includes a geometry and an epitaxial layer thickness configured to enable a predetermined light extraction, including a predetermined extraction into a cone angle.

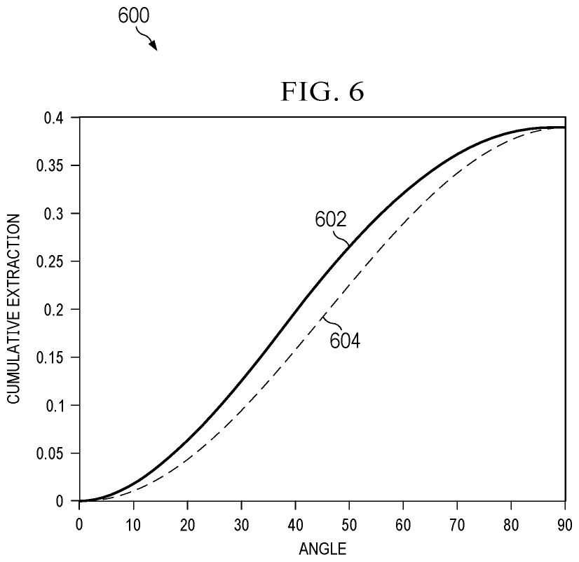

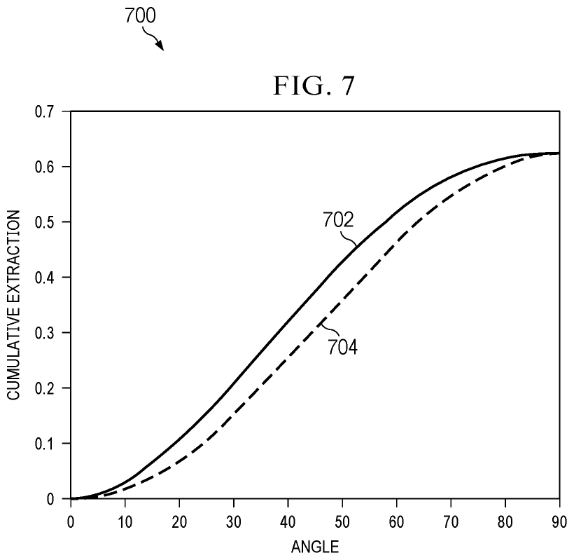

FIGS. 6 and 7 are graphs 600, 700 of light extraction into air vs. angle from the micro-LED 100 with slanted sidewalls 102 in accordance with some embodiments. The cumulative extraction at angle theta is defined as the extraction within a cone of angle theta (hence, the cumulative extraction at 90 degrees is the total extraction into air). Graphs 600, 700 illustrate comparative light extraction into air of the micro-LED 100 versus Lambertian emitters (i.e., standard LEDs without preferential directions of light emission). FIG. 6 shows a curve 602 of light extraction into air from a micro-LED 100 having slanted non-vertical sidewalls 102 with gamma=35 degrees, compared to a curve 604 of light extraction from a Lambertian LED having the same total extraction. The micro-LED 100 has higher extraction than a Lambertian LED at all angles. For instance, in the illustrated embodiment, the micro-LED 100 extracts 30% more light in a 30 degree cone than a Lambertian LED. The enhanced light extraction from the micro-LED 100 is enabled by the joint configuration of interference effects and the geometry of the micro-LED 100, such that light is preferentially extracted in some directions. FIG. 7 shows a similar comparison for gamma=75 degrees. The embodiment in which gamma=75 degrees extracts 40% more light in a 30 degree cone than a Lambertian LED.

The structure of FIG. 1 is simple, with a fully-singulated micro-LED 100. In some embodiments, a display includes arrays of micro-LEDs grown on the same wafer. Some arrays of micro-LEDs include pixels, with each pixel having several subpixels (i.e., red, green and blue for an RGB display). The pitch of an array is a characteristic distance between pixels; the subpitch of an array is a characteristic distance between subpixels.

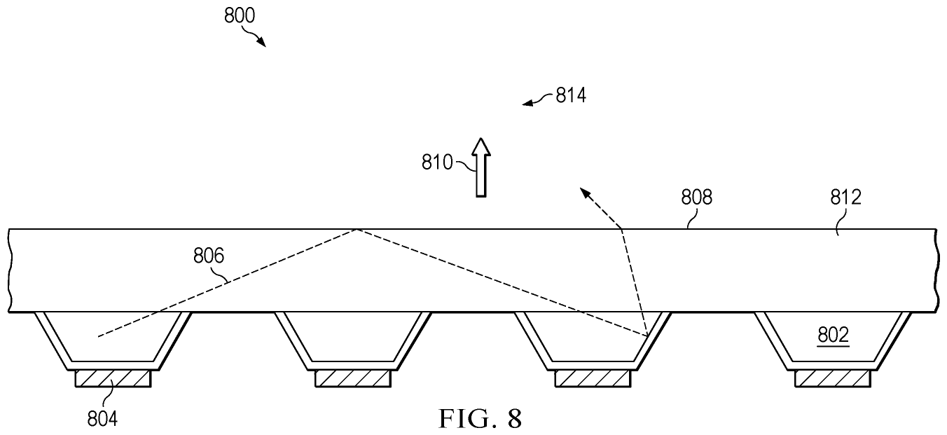

FIG. 8 is a diagram of a light trajectory from a display 800 with an array of multiple micro-LEDs forming an array of subpixels 802 with slanted sidewalls in accordance with some embodiments. The display 800 emits display light in an emission direction 810—in this case, perpendicular to the display output surface 808 (also referred to as output facet 808). The subpixels 802 and the member 812 above them are made of semiconductor material. Contacts 804 are formed to each subpixel 802 to enable electrical driving (only one contact is shown in the illustrated example; in other embodiments two contacts 804 are formed on each subpixel 802 or, in other embodiments, the subpixels 802 share a common electrode). A light trajectory 806 from one subpixel 802 is reflected by the output facet 808 of the array (due to the index contrast between the semiconductor member 812 and an outside medium 814 such as the air on top of the display 800), and extracted by another subpixel 802. Such a trajectory is detrimental to the resolution of the display, as light emitted by one subpixel 802 is extracted far away from the emitting subpixel 802. The light extraction (Cex) of a subpixel 802 is the fraction of the light emitted by the subpixel 802 that escapes the display output facet.

Some embodiments improve upon the local light extraction exhibited by the display 800 by ensuring that light emitted by a subpixel 802 is extracted in the vicinity of the subpixel 802. Accordingly, some embodiments of a display include arrays of micro-LEDs 100, wherein light emitted by a micro-LED 100 is substantially extracted within a predetermined lateral distance from the micro-LED 100. In some embodiments, the pitch of the array is P (with P less than 20 um, 10 um, 5 um, 4 um, 3 um, 2 um), and at least 50% (or 70%, 80%, 90%, 95%) of the light extracted from a subpixel 802 escapes from the display 800 within a lateral distance of P (or 2P, 3P, 5P, 10P) from the center of the subpixel 802. Enhanced localization of light extraction is combined with a light extraction higher than a predetermined value (e.g., at least 10%, 15%, 20%, 25%, 30%, 35%, 40%, 45%, 50%) in some embodiments, as described in further detail below.

### Low-Index Layer

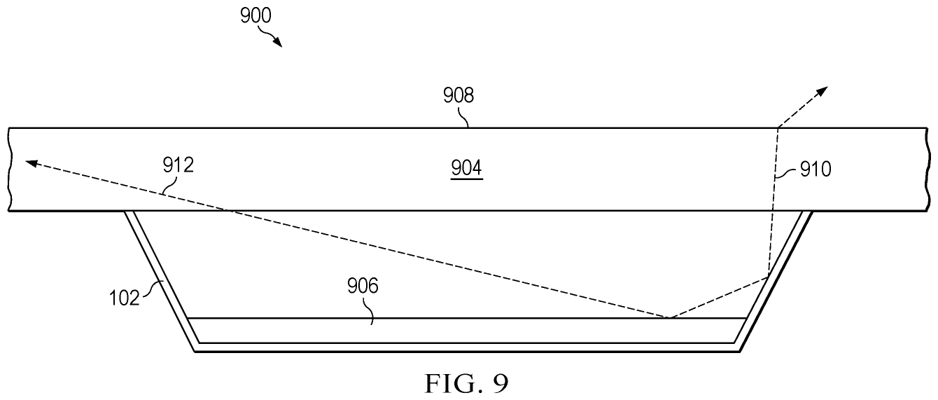

FIG. 9 is a diagram of light trajectories emitted at a large angle from an active region 906 of a micro-LED 900 with slanted sidewalls 102 in accordance with some embodiments. A first trajectory 910 emitted at a large angle (e.g., 60 degrees with respect to normal) from the active region 906 escapes through the output facet 908 after bouncing off the slanted sidewall 102. A second trajectory 912 emitted at a large angle from the active region 906 travels sideways through a semiconductor layer 904 and does not interact with the slanted sidewall 102. The second trajectory 912 may be absorbed farther in the display or be extracted far away from the pixel 900. In some cases, neither of these scenarios is desirable. To prevent light emitted at large angles from the active region 906 from being lost or being extracted far from the pixel 900, some embodiments of the micro-LED include a low-index layer.

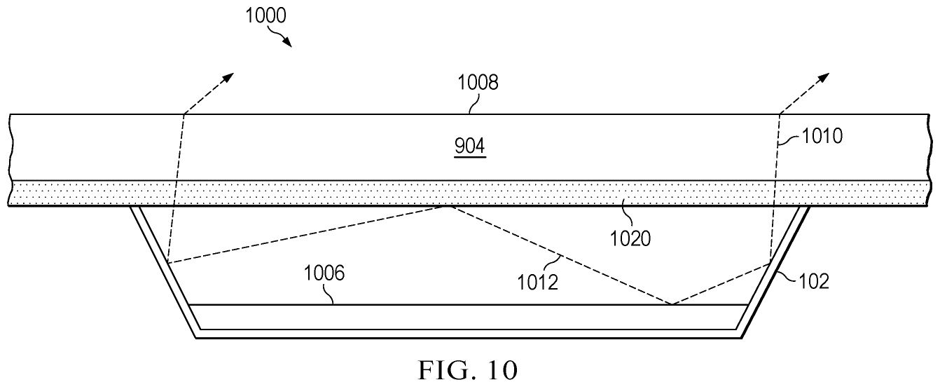

FIG. 10 is a diagram of light trajectories from a micro-LED 1000 with slanted sidewalls 102 and a low-index semiconductor layer 1020, referred to herein as a low-index layer or LIL 1020, in accordance with some embodiments. The semiconductor 904 includes a LIL 1020 positioned near the region where the pixel mesa connects to the body of the display. The LIL 1020 has an index of refraction that is lower than the index of refraction of the surrounding semiconductor 904. The surface of the LIL 1020 rests on the semiconductor 904 parallel to the light-emitting region and acts as an optical interface between the high-index semiconductor 904 and the LIL 1020 that reflects light impinging at large angles (due to total internal reflection (TIR)) and is transparent to light impinging at near-normal angles.

Similar to the first trajectory 910 of FIG. 9, a first light trajectory 1010 emitted at a large angle from the active region 1006 escapes through the output facet 1008 after bouncing off the slanted sidewall 102, because the first light trajectory 1010 impinges on the LIL 1020 at a near-normal angle. By contrast, a second trajectory 1012 emitted at a large angle from the active region 1006 impinges the LIL 1020 at a large angle and is reflected towards the slanted sidewall 102, from which the second light trajectory 1012 is reflected at a near-normal angle to the LIL 1020 and is extracted in the pixel's vicinity. Thus, embodiments of the micro-LED 1000 having slanted sidewalls 102 and a LIL 1020 increase both light extraction and localized light extraction. Some embodiments include displays having a semiconductor body with several pixels and at least one LIL configured to reflect light at large angles, increasing both light extraction and localized light extraction.

### Secondary Optics

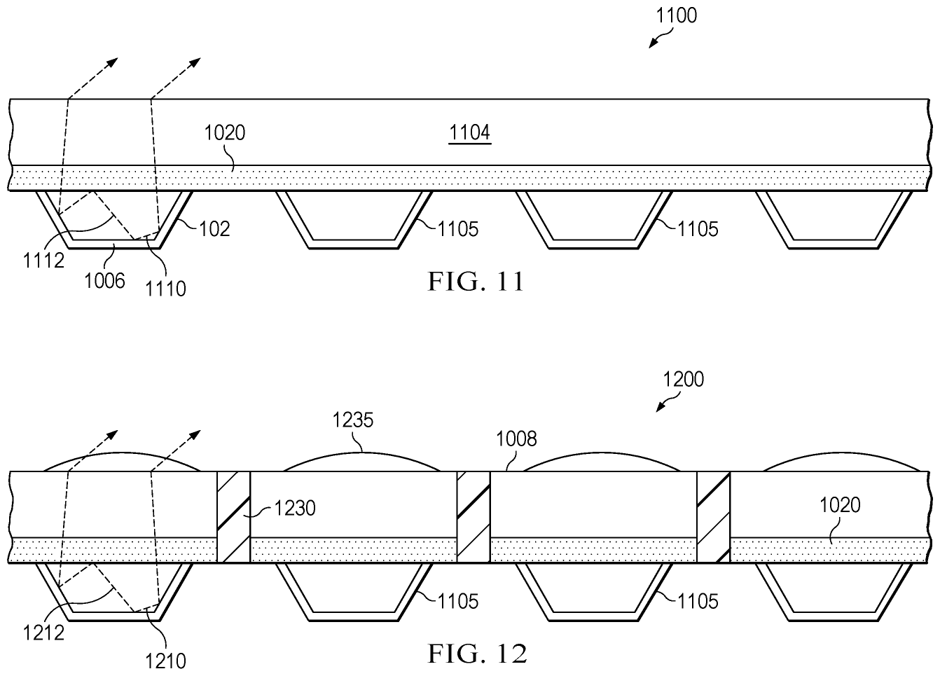

FIGS. 11, 12, 13, and 14 illustrate embodiments including arrays of multiple micro-LEDs with slanted sidewalls and secondary optical features. FIG. 11 is a diagram of a first light trajectory 1110 and a second light trajectory 1112 from a display 1100 with an array of multiple micro-LEDs 1105 with slanted sidewalls 102 connected by a semiconductor body 1104 having a low-index layer 1020 in accordance with some embodiments. The first light trajectory 1010 is emitted at a large angle from the active region 1006 and escapes through the output facet 1008 after bouncing off the slanted sidewall 102, because the first trajectory 1110 impinges on the LIL 1020 at a near-normal angle. Similar to the second trajectory 1012 of FIG. 10, the second trajectory 1112 is emitted at a large angle from the active region 1006 and impinges the LIL 1020 at a large angle such that it is reflected towards the slanted sidewall 102. The second trajectory 1112 is reflected from the slanted sidewall 102 at a near-normal angle to the LIL 1020 and is extracted in the pixel's vicinity. Thus, the combination of the slanted sidewalls 102 and the LIL 1020 for each of the multiple micro-LEDs 1105 in the array causes each micro-LED 1105 to have more light extracted and more light extracted in the region of the emitting micro-LED 1105.

FIG. 12 is a diagram of a first light trajectory 1210 and a second light trajectory 1212 from a display 1200 with an array of multiple pixels. Each pixel is a micro-LED 1105 with slanted sidewalls 102. The display 1200 further includes a low-index layer 1020, optical isolation features 1230, and secondary optical features 1235 in accordance with some embodiments. The slanted sidewalls 102 and the LIL 1020 cause the first light trajectory 1210 and the second light trajectory 1212 to be extracted at near-normal angles to the output facet 1008, as described above with respect to FIG. 11.

The optical isolation features 1230 include reflecting or absorbing material which prevents cross-talk between pixels (i.e., prevents light emitted by one pixel from escaping above another pixel). The secondary optical features 1235 further increase the light extraction and the directionality of the emission from the pixel. In the illustrated example of FIG. 12, the secondary optical features are lenses. Lenses can collimate or re-direct light and facilitate a more directional emission. In some examples, a lateral extent of a lens is larger than a lateral extent of a corresponding light-emitting region, e.g., by 1.5 times (or 2 times, 3 times), facilitating a collimating effect by the lens.

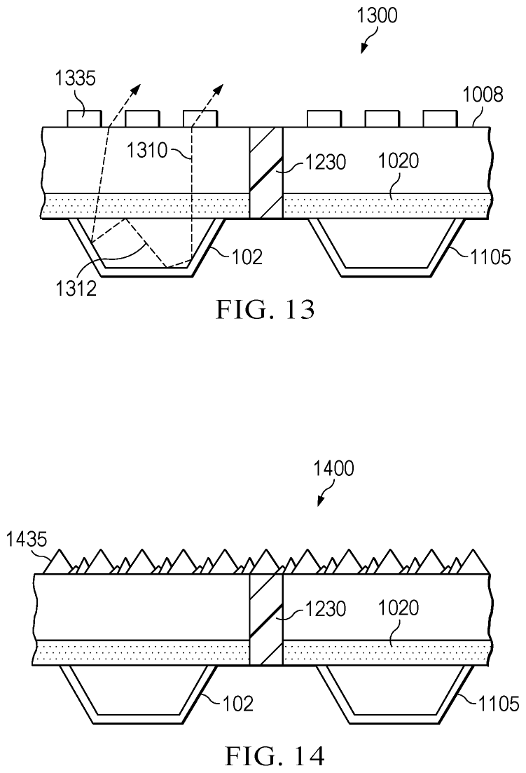

FIG. 13 is a diagram of a first light trajectory 1310 and a second light trajectory 1312 from a display 1300 with an array of multiple pixels. Each pixel is a micro-LED 1105 with slanted sidewalls 102, a low-index layer 1020, optical isolation features 1230, and periodic or quasi-periodic secondary optical features 1335 in accordance with some embodiments. The slanted sidewalls 102 and the LIL 1020 cause the first light trajectory 1310 and the second light trajectory 1312 to be extracted at near-normal angles to the output facet 1008, as described above with respect to FIG. 11.

In the illustrated example of FIG. 13, the secondary optical features 1335 are periodic (or quasi-periodic) structures. In some embodiments, the secondary optical features 1335 form a macroscopic pattern, a photonic crystal, or a meta-lens. Such diffractive structures may (1) coherently diffuse the light in preferred directions, thus facilitating a directional emission and (2) diffract large-angle light, which would otherwise be trapped by total internal reflection, thus increasing total light extraction.

FIG. 14 is a diagram of a display 1400 with an array of multiple pixels. Each pixel is a micro-LED 1105 with slanted sidewalls 102, a low-index layer 1020, optical isolation features 1230, and a secondary optical feature 1435 that is a random surface in accordance with some embodiments. Such a random surface can scatter (diffuse) the light in random directions, thereby breaking guided trajectories and increasing light extraction. In some embodiments, the addition of optical isolation features and secondary optical features as illustrated in FIGS. 11-14 to an array of micro-LEDs having slanted sidewalls 102 and a low-index layer 1020 results in less than 20% (or 10%, 5%) of the light emitted by a pixel travelling laterally to another pixel inside the display.

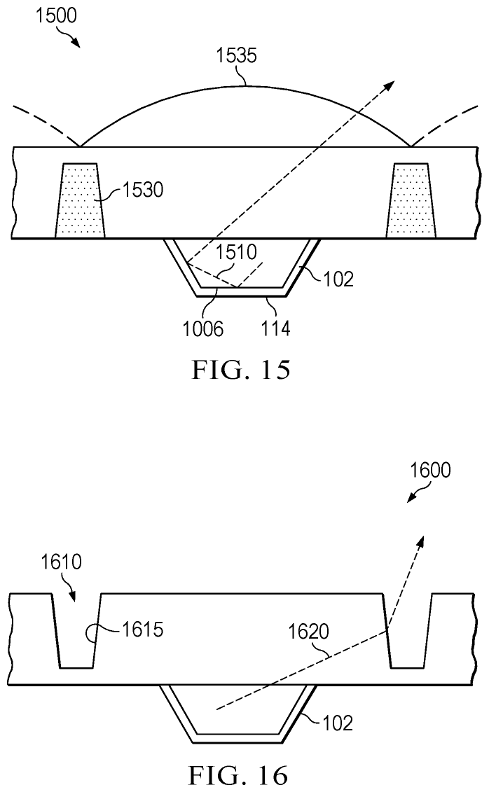

FIGS. 15, 16, 17, 18, and 19 show additional geometries for secondary optical extraction features. In each of FIGS. 15, 16, 17, 18, and 19, only one sub-pixel (micro-LED) is shown. FIG. 15 is a diagram of a sub-pixel micro-LED 1500 with a bottom mirror 114, slanted sidewalls 102, non-vertical optical isolation features 1530 and a lens-like secondary optical extraction feature, lens 1535, in accordance with some embodiments. The lens 1535 is substantially spherical, elliptical, parabolic, or has other shapes known in the art, in various embodiments. A light trajectory 1510 is emitted from the active region 1006, from which the light trajectory 1510 bounces off the bottom mirror 114, is reflected off the sidewall 102 of the subpixel, and is then extracted by the lens 1535.

FIG. 16 is a diagram of a sub-pixel micro-LED 1600 with slanted sidewalls 102, non-vertical optical isolation features in the form of lateral trenches 1610 etched in the semiconductor. The trenches 1610 have slanted sidewalls 1615, suited to re-direct light near the vertical direction. A light trajectory 1620 is shown in which light propagating at large angles in the semiconductor is redirected by the trench 1610 toward the display direction. In this case, the trench may act both as the secondary optical feature and as the optical isolation feature.

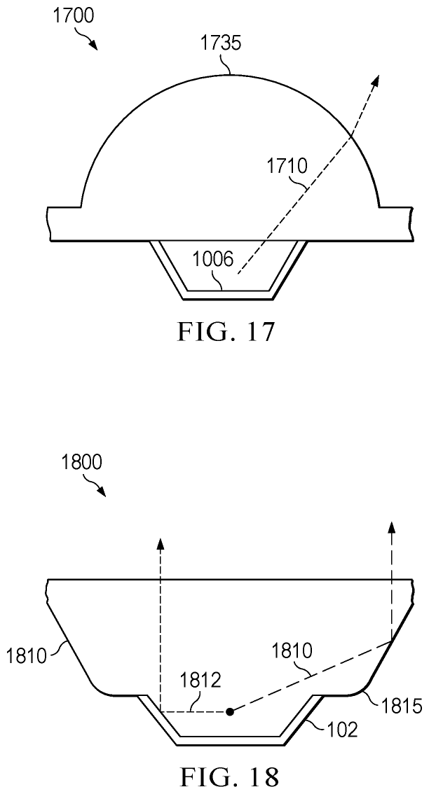

FIG. 17 is a diagram of a sub-pixel micro-LED 1700 with slanted sidewalls 102, and a lens-like secondary optical extraction feature, lens 1735, in accordance with some embodiments. The lens-like secondary optical extraction feature 1735 is etched in the semiconductor in some embodiments. An illustrated light trajectory 1710 is emitted at a large angle from the active region 1006 and is directed to an angle closer to normal by the lens-like secondary optical extraction feature 1735.

FIG. 18 is a diagram of a sub-pixel micro-LED 1800 with slanted sidewalls 102 having a reflective coating and curved (e.g., parabolic) shapes 1815 etched in the semiconductor body. A first light trajectory 1810 impinges on the curved shapes 1815 and is reflected, e.g., by total internal reflection, before being extracted at a near-normal angle from the sub-pixel micro-LED 1800. A second light trajectory 1812 impinges on the non-vertical sidewalls 102, from which it is reflected and extracted at a near-normal angle from the sub-pixel micro-LED 1800.

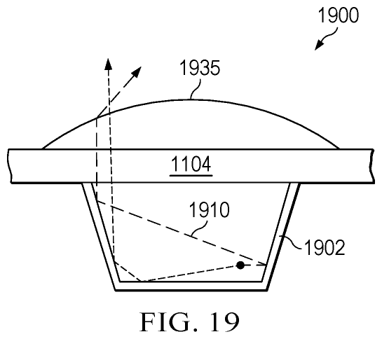

FIG. 19 is a diagram of a sub-pixel micro-LED 1900 that has a tall, curved sidewall 1902 with a compound parabolic reflector (CPC)-like profile connected to the semiconductor body 1104 and a secondary optical extraction feature 1935. The curved shape of the sub-pixel micro-LED 1900 is obtained by epitaxy, by etching, or by a combination thereof in some embodiments. A light trajectory 1910 impinging on the curved sidewall 1902 is directed towards the secondary optic 1935, which facilitates light extraction in a near-normal direction.

Secondary optical features are imparted by the growth substrate (e.g., when growing on patterned sapphire or silicon, the patterns may form the secondary optical features) in some embodiments, or are etched in the semiconductor body 1104 after the substrate is removed in other embodiments. Semiconductor optical features are formed in some embodiments by adding a material, such as a resist or a dielectric or other transparent material, on the semiconductor member. In some embodiments, the material is spun-on, evaporated, sputtered, or deposited by other known techniques. The material is reflown to impart it with a desired shape (for instance, to ball-up and assume a lens-like shape) in some embodiments. The material may have a relatively high index to avoid reflection at the interface with the semiconductor; for example, the index of refraction of the material is at least 1.4 (or 1.5, 1.6, 1.8, or 2) in various embodiments. Suitable high-index materials include TiO2, Ta2O5, and AIOx.

The lateral dimension of the secondary optic is at least 1.5×(or 2×, 3×) the lateral dimension of the light-emitting region in some embodiments to facilitate focusing of light. For instance, some embodiments of a sub-pixel micro-LED have a light emitting region with a diameter of approximately 1.5 μm, and a secondary optic with a diameter of approximately 2.5um.

In some embodiments, it is desirable to thin down the overall semiconductor thickness to avoid light traveling large lateral distances before extraction. For example, display having mesas with a thickness less than 2 um (or 1 um, 750 nm, 500 nm, 250 nm) grown on a semiconductor member (i.e., a III-Nitride buffer) is thinned down to less than 5 um (or 3 um, 2 um, 1.5 um, 1 um) in some embodiments. Thinning techniques include polishing, grinding, CMP, etching, laser lift-off, wet etch, selective etch, and combinations thereof. In some embodiments, a GaN-based buffer (e.g., with a thickness of 5 m) is grown on a substrate and is used as a base to grow uLED pixels. After epitaxy, p-contact formation, and substrate removal, the buffer is thinned to 2 um, and secondary optical elements are formed on the buffer.

In some embodiments, the thickness separating the subpixels from the secondary optical elements is substantially constant across the display. For example, in some embodiments the subpixels have light-emitting regions and the secondary optical elements are micro-lenses, and the vertical distance between an active region and the corresponding micro-lens is constant within +/−1 um (or 500 nm, 200 nm, 100 nm, 50 nm) across the display to facilitate light output uniformity and help the optical coupling to the micro-lenses.

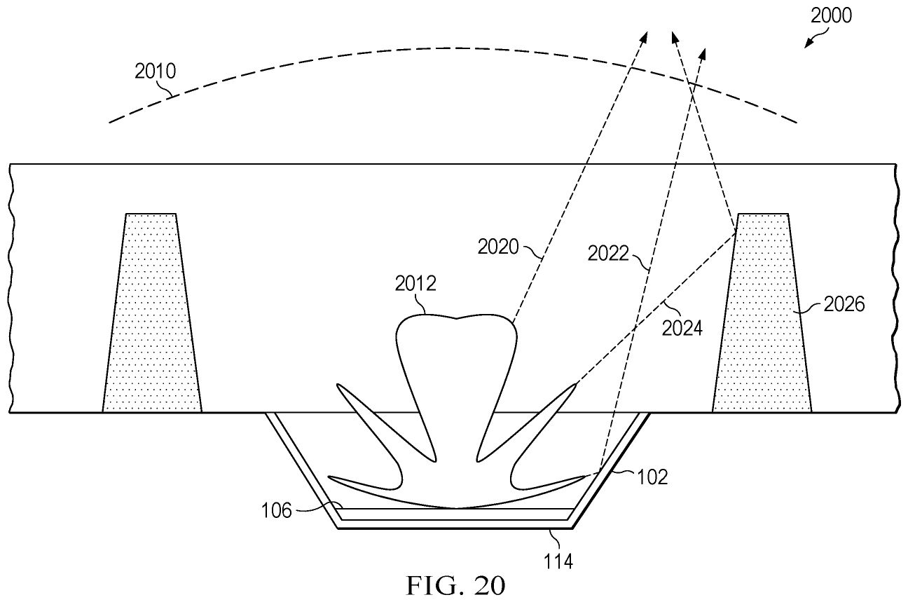

FIG. 20 is a source emission diagram 2012 of a sub-pixel micro-LED 2000 with slanted sidewalls and secondary extraction features in accordance with some embodiments. FIG. 20 illustrates how the emission properties of the active region 106 of the sub-pixel micro-LED 2000 are jointly configured with the device geometry to achieve a high level of light extraction. The active region 106 is located in optical proximity to the bottom mirror 114 and slanted sidewalls 102, giving rise to interference, which results in the source emission diagram 2012 with light being emitted in preferential directions (i.e., preferential angular ranges) 2020, 2022, 2024. The distance between the active region 106 and the bottom mirror 114, and the optical indices of various layers (referred to as the geometry of the display) are selected to configure the source emission diagram 2012. The geometry of the display is further configured to efficiently extract light emitted in the preferential directions. A first direction 2020 is directly extracted by a secondary optical element 2010. A second direction 2024 bounces off an optical feature 2026 (e.g., an isolation feature) and is extracted through the secondary optical element 2010. A third direction 2022 is reflected by the non-vertical slanted sidewall 102 and is extracted through the secondary optical element 2010. Each of the first, second, and third directions 2020, 2022, 2024 has a light extraction efficiency of at least 30% (or 50%, 70%) in some embodiments.

In some embodiments, a sufficient fraction of the total emitted light (i.e., at least 5%, 10%, 15%) is emitted in a desired direction, such as the first, second, or third direction 2020, 2022, 2024. The direction has an angular width such as, for example, at least 10% of the total emitted light is emitted within +/−5 deg (or 10 deg) of the first direction 2020; at least 10% of the total emitted light is emitted within +/−5 deg (or 10 deg) of the second direction 2024.

More generally, the direction of light is characterized quantitatively by an angular range—such as +/−1 deg (or 2 deg, 5 deg, 10 deg, 15 deg, 20 deg) around a given angle. In some embodiments, the angle is a polar angle and the angular range describes a ring of angles (i.e., angles having any azimuthal angle, and having a polar angle within the range).

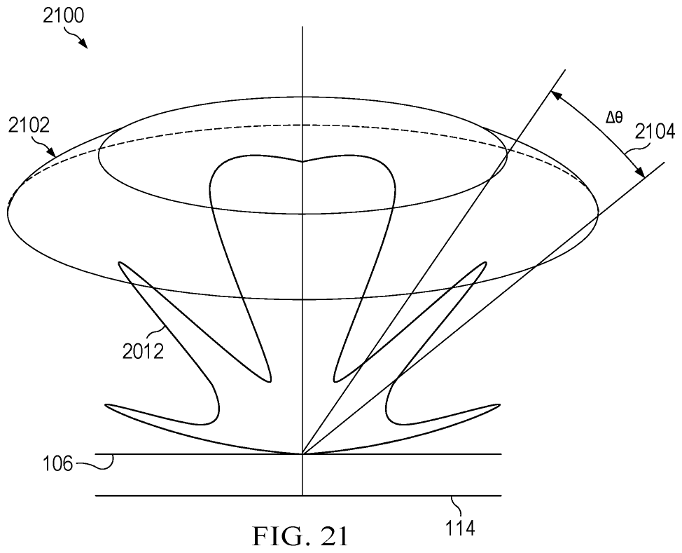

FIG. 21 is a source emission diagram 2100 in which light emission is enhanced in some directions and light emission is inhibited in some directions in accordance with some embodiments. In FIG. 21, a bottom mirror 114 is in optical proximity to a light emitting region 106. The bottom mirror 114 and the light-emitting region 106 are jointly configured to produce interference effects, resulting in the source emission diagram 2100 with some directions where light emission is enhanced and some directions where light emission is inhibited. FIG. 21 shows a polar angle range 2104 in which emission is enhanced, and the corresponding angular ring 2102 - i.e., the locus of all azimuthal angles corresponding to the polar angle range 2104. Although not shown, a non-vertical (slanted) sidewall 102 also affects the source emission diagram 2100 in some embodiments. In some embodiments, an optical interface (e.g., a secondary optical element) is designed to facilitate light extraction based on the source emission diagram 2100. In some embodiments, the optical interface and the source emission diagram 2100 are jointly optimized to improve extraction.

Some embodiments include methods to model light extraction and design devices for improved extraction, including micro-LED displays. Some embodiments include combining a wave-optics model and a geometric-optics model such as raytracing. The wave-optics model is used to compute the interaction between the source and optical elements in a vicinity of the source (for instance, located less than 10 wavelengths away), such as optical interference with a proximate mirror and/or waveguiding effects in some embodiments. The raytracing model takes the result of the wave-optic model and computes light extraction on a larger scale—for instance, the effect of non-vertical sidewalls, secondary optical elements and other optical features. The wave-optics and geometric-optics models are jointly used to improve light extraction in some embodiments. Some embodiments include a method of computing light extraction out of a display, in a given direction, which is higher than a predetermined value (e.g., more than 10% or 15% or 20% in a +/−30 deg cone).

### Isolation Features

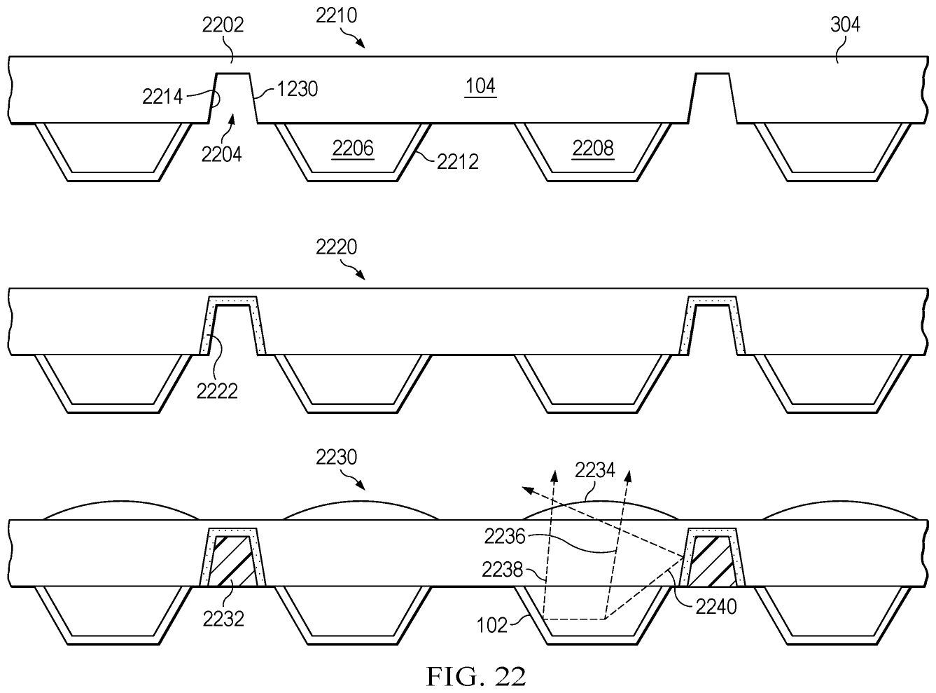

FIG. 22 shows how optical isolation features, such as optical isolation features 1230, are formed in some embodiments. Optical isolation features aid in preventing light from traveling between sub-pixels or between pixels. In the case of FIG. 22, a pixel 2212 comprises two sub-pixels 2206, 2208 and optical isolation features 1230 are formed at the periphery of the pixel 2212. In step 2210, cavities 2204 are etched between the pixels 2212. In some embodiments, the etch is a dry etch having a depth that is formed throughout the semiconductor layer 304. In some embodiments, the etching processes leaves an un-etched region 2202, as illustrated in step 2210. The semiconductor layer 304 is also thinned from the top side (either before or after the cavity 2204 is etched) in some embodiments. The un-etched region 2202 is thin enough to prevent light leakage and be thick enough to maintain mechanical integrity. The un-etched region 2202 is less than 2 um thick (or 1 um, 500 nm) in some embodiments, and the cavity 2204 has a vertical or a non-vertical profile, depending upon the implementation. In the case of a non-vertical profile, a sidewall 2214 of the cavity 2204 may have an angle (with respect to the vertical direction) of at least 5 deg (or 10 deg, 20 deg, 30 dg).

In step 2220, an insulating layer 2222 is deposited in the cavity. The insulating layer 2222 is a dielectric (such as SiN, SiOx, TaOx, AIOx) in some embodiments and may be conformal. The insulating layer 2222 covers both the sidewalls and the end of the cavity 2204 in some embodiments.

In step 2230, a reflective layer 2232 is deposited over the insulating layer 2222, and micro-optics 2234 are formed. The reflective layer 2232 may be a metal (such as an Ag-based or Al-based metal). The thickness of the metal may be larger than the skin depth of visible light in the metal. The reflective layer 2232 may instead be a multi-layer reflector (such as a dichroic mirror). The reflectivity of the reflective layer 2232 may be at least 80%. The thickness of the insulating layer 2222 may be configured to increase reflectivity (for instance due to interference effects which enhance reflection). In step 2230, several light trajectories 2236, 2238, 2240 are shown. A first trajectory 2236 escapes the display directly; a second trajectory 2238 reflects off the micro-LED sidewall 102 and then escapes the display; a third trajectory 2240 reflects off the isolation feature 1230 and then escapes the display.

The isolation feature 1230 may be configured jointly with other properties of the display to enhance light extraction, as taught herein. For example, in some embodiments the distance between the active region 106 and the bottom mirror 114 is jointly configured with the angle of the isolation feature 1230.

### Low-Index Layer

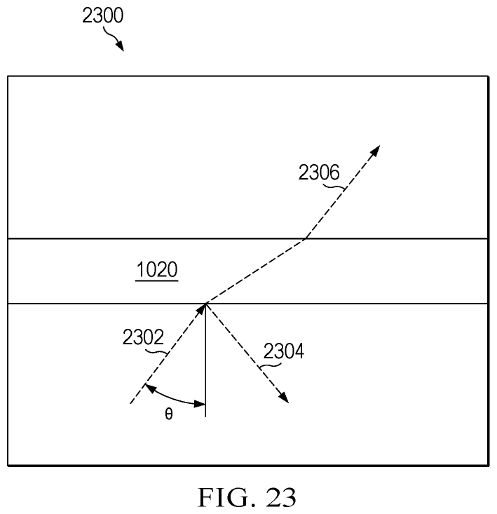

Although a low-index layer (LIL) 1020 is not shown on the optical designs of FIGS. 15- 22, an LIL may be integrated in such designs to increase light extraction, as shown in FIGS. 10-14. FIGS. 23, 24, and 25 show how the LIL 1020 can reflect light at large angles. FIG. 23 is a diagram 2300 illustrating a light trajectory 2302 with respect to a low-index layer 1020 in accordance with some embodiments. FIG. 23 shows the modeled geometry, with light 2302 impinging at angle theta from a semiconductor material on a LIL 1020. A first portion 2304 of the light 2302 is reflected off the LIL 1020 and a second portion 2306 is diffracted and transmitted through the LIL 1020.

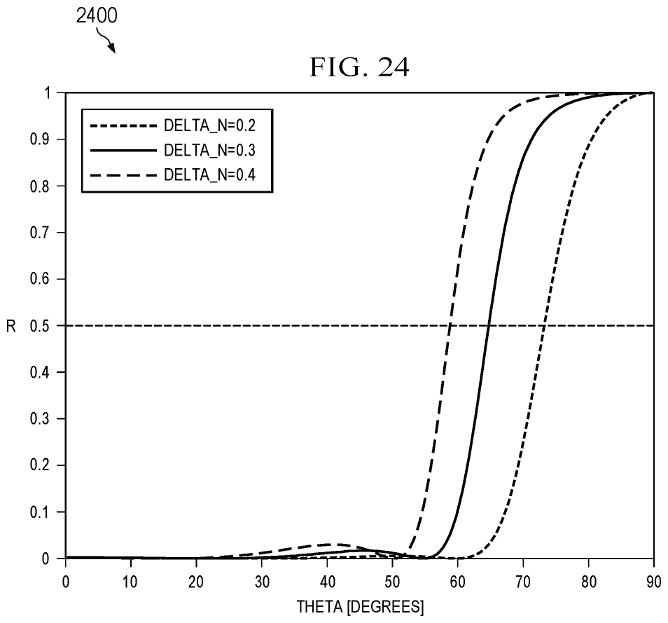

FIG. 24 is a graph 2400 illustrating the reflectivity R of a low-index layer 1020 as a function of an angle of incidence theta in accordance with some embodiments. In this calculation, the thickness of the LIL 1020 is half the wavelength of the light. The reflectivity depends on the index contrast delta_n between the semiconductor and the LIL 1020. The reflectivity can be characterized by the angle theta50 where reflectivity crosses a value of 50%. For delta_n=0.2/0.3/0.4, theta50=65/60/55 deg.

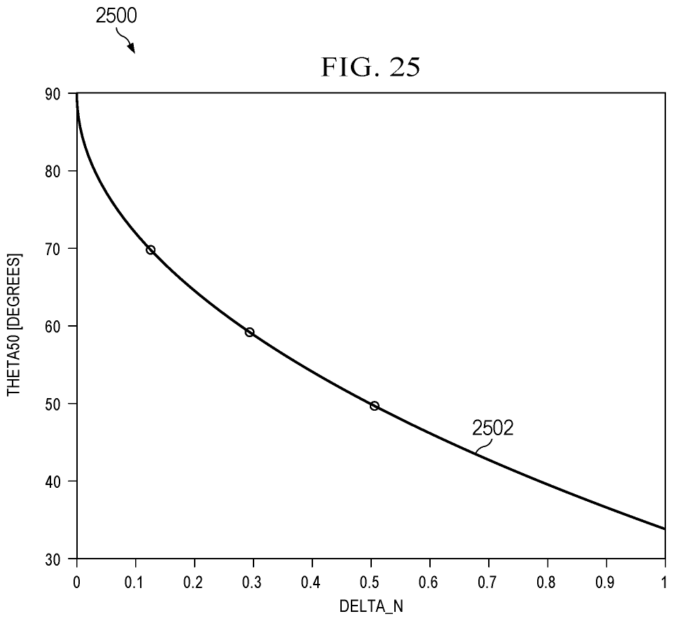

FIG. 25 is a graph 2500 illustrating the reflectivity of a low-index layer 1020 as a function of the index contrast between the semiconductor and the low-index layer in accordance with some embodiments. FIG. 25 illustrates a curve 2503 of theta50 as a function of delta_n. By selecting delta_n, light can be reflected for angles above a desired theta50.

The reflection off the LIL 1020 is a total internal reflection (TIR), caused by the lower index of the LIL 1020 with respect to the layer from which light is coming. Light emitted at large enough angle undergoes TIR and can be termed “TIR light”. In some embodiments, at least 10% (or 20%, 30%, 50%) of the light emitted by the active region 106 is emitted as TIR light. The micro-LED may further be configured to efficiently extract the TIR light, or a fraction thereof.

In some embodiments, a light trajectory reflects once off the LIL 1020 and once off a non-vertical sidewall 102 before being extracted. In some embodiments, a light trajectory reflects once off the bottom mirror 114, once off the LIL 1020 and once off a non-vertical sidewall 102 before being extracted. In some embodiments, light emission into such a trajectory is enhanced by constructive optical interference, as taught herein. In some embodiments, such a trajectory has a light extraction efficiency of at least 50% (or 60%, 70%, 80%)—meaning that at least 50% of the light emitted in that trajectory escapes from the micro-LED.

Some embodiments include micro-LEDs having at least one light-emitting layer, a matrix of semiconductor in the surrounding the light-emitting layer, and a LIL. In some embodiments, the light-emitting layer is an InGaN layer (with an In composition C1) and the matrix is GaN or InGaN (with an In composition C2, with C2<C1). The matrix has an index n_matrix, the LIL has an index n_LIL, and n_LIL is lower than n_matrix minus 0.1 (or 0.2, 0.5, 0.4, 0.5, 0.6, 0.7, 1, 1.5).

In a specific example, an epitaxial stack has the following layers grown in succession: n-doped AlInN LIL; n-doped GaN layer; n-doped InGaN layer; active region comprising one or several InGaN light emitting layers; p-doped InGaN layer; p-doped GaN layer. Other layers may be added. In this example, the matrix is GaN, and the GaN/AlInN interface causes TIR for light propagating at large angles.

In some embodiments, the LIL is not spatially homogeneous (in particular, it may be inhomogeneous on a scale smaller than the wavelength of light). In such cases, the index of the LIL can be defined as the spatially-averaged index over the LIL. In addition, a non-homogeneous LIL may cause light scattering. In some embodiments, the light scattering is configured to enhance light extraction.

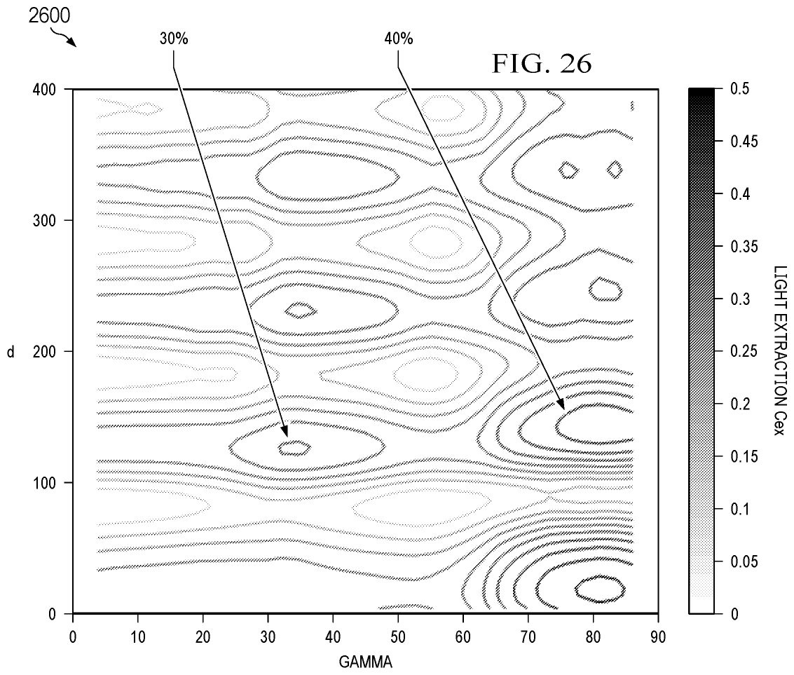

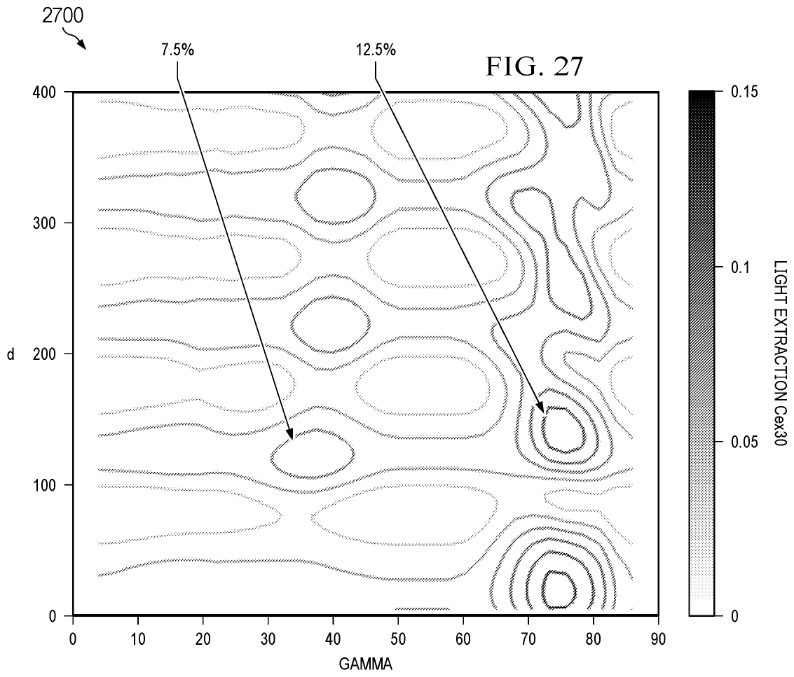

FIGS. 26 and 27 are graphs illustrating the light extraction from a micro-LED without a low-index layer (i.e., with the geometry illustrated in FIG. 9) in accordance with some embodiments. For purposes of FIGS. 26 and 27, light escaping the vicinity of the pixel (i.e., light outside the dashed lines of the light trajectories depicted in FIG. 9) is considered lost. FIG. 26 shows a graph 2600 of the total light extraction (Cex). FIG. 27 shows a graph 2700 the light extraction in a 30 deg cone (Cex30). As in FIGS. 4 and 5, some slant angles and some values of d lead to higher values of Cex and Cex30. However, the values are lower than in FIGS. 4 and 5 because a substantial fraction of the light is escaping the pixel.

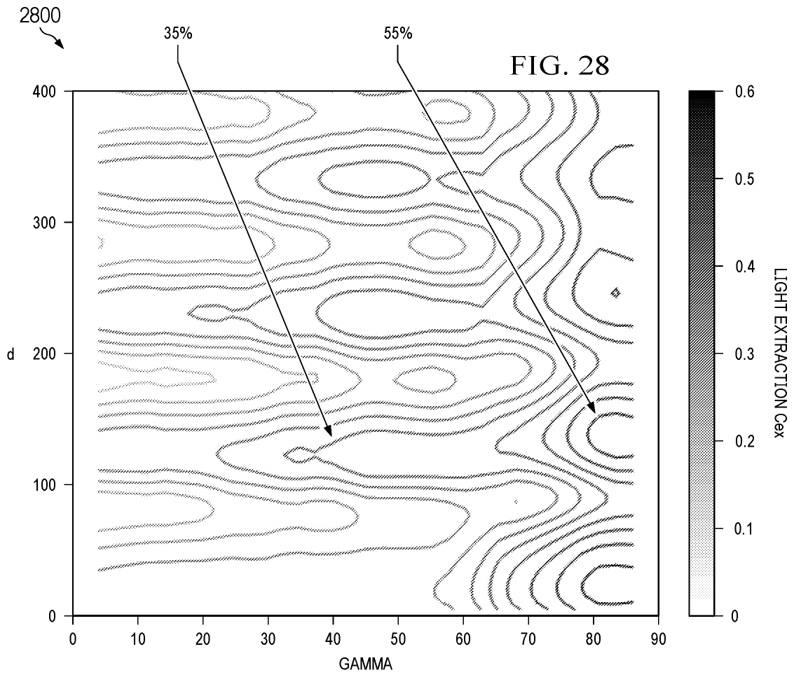

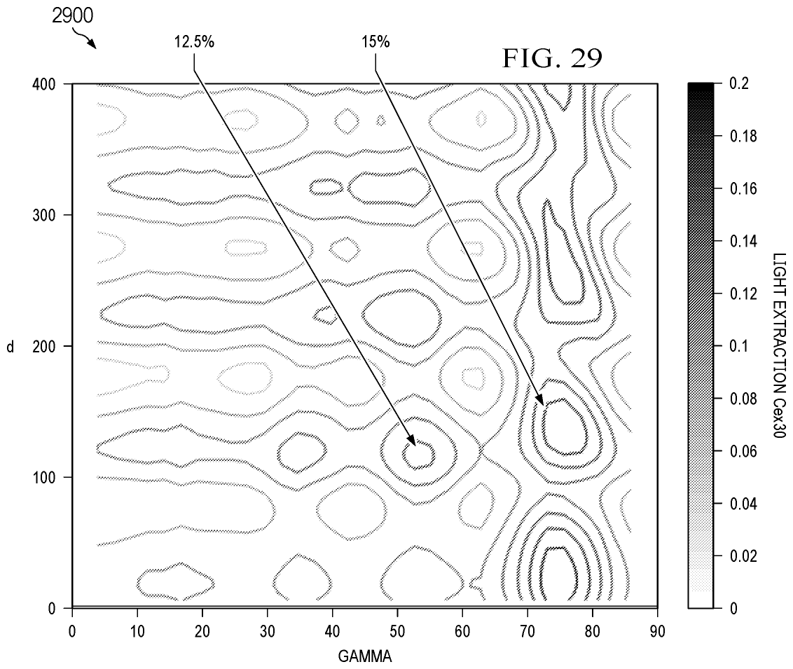

FIGS. 28 and 29 are graphs illustrating the light extraction from a micro-LED with a low-index layer (i.e., with the geometry illustrated in FIG. 10) in accordance with some embodiments. FIG. 28 shows a graph 2800 of the total light extraction (Cex) and FIG. 29 shows a graph 2900 of the light extraction in a 30 deg cone (Cex30). Both Cex and Cex30 are increased over the values of FIGS. 28 and 29, because the LIL enables large-angle light to be extracted above the pixel. Some embodiments lead to values of Cex above 35% (for gamma ˜30-50 deg) or 55% (for gamma ˜80 deg). Some embodiments lead to values of Cex30 above 12.5% (for gamma ˜55 deg) or 15% (for gamma ˜75 deg). Lower values of gamma may be desirable to limit the footprint of the LED mesa. Therefore, it may be desirable to select a value of gamma in the range 30-60 degrees and configure the micro-LED geometry to increase light extraction and local light extraction.

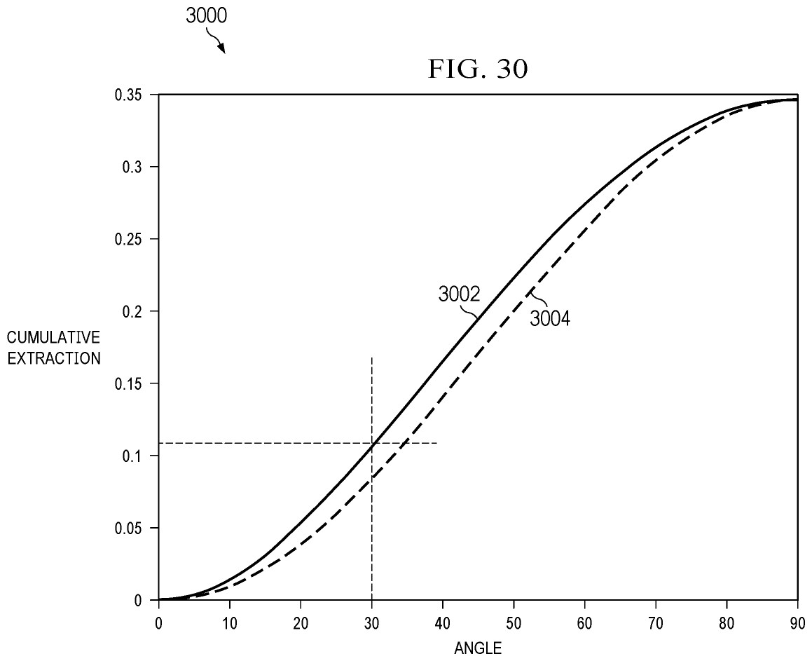

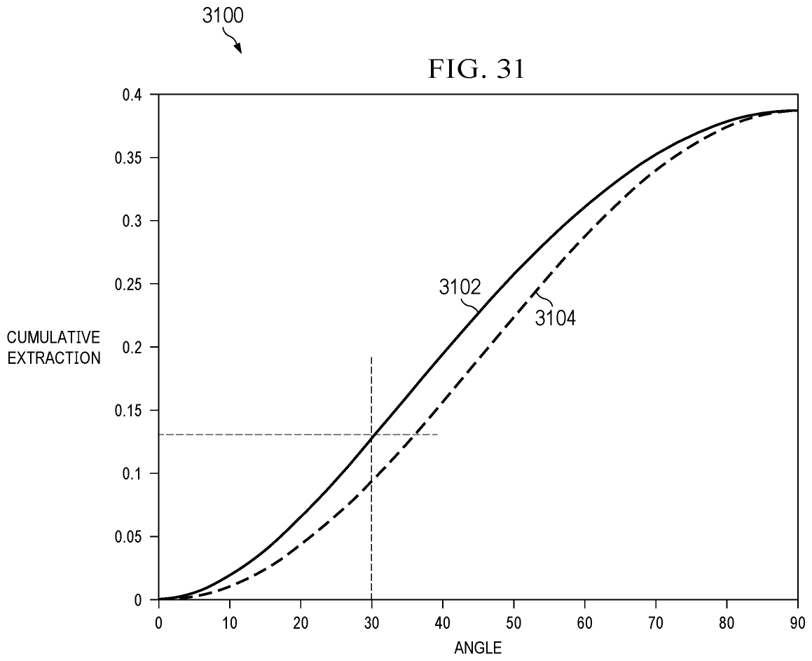

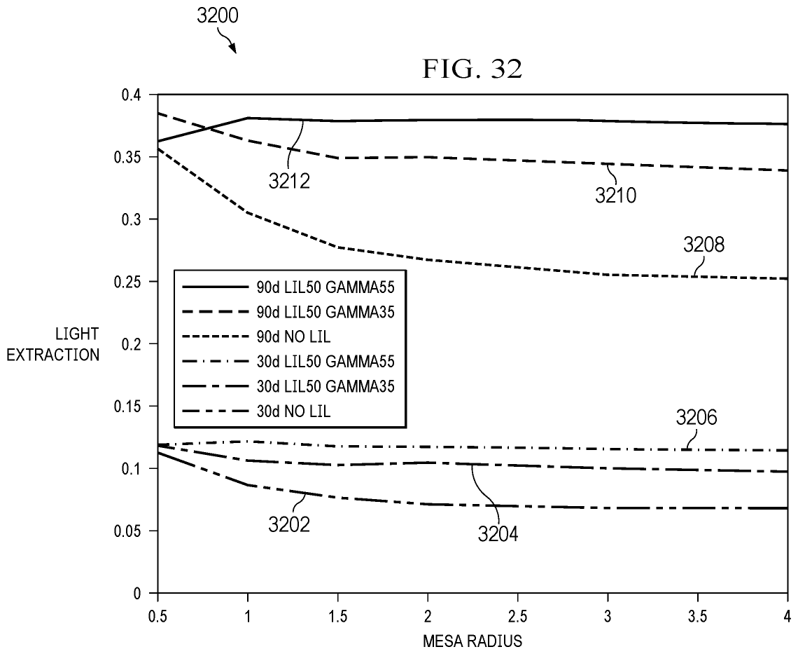

FIGS. 30 and 31 are graphs 3000, 3100, similar to those of FIGS. 6 and 7, illustrating light extraction into air as a function of angle for a micro-LED corresponding to the geometry of FIG. 10 in accordance with some embodiments. FIGS. 30 and 31 correspond to specific points on the contour maps of FIGS. 28 and 29. FIG. 30 shows a curve 3002 of light extraction into air from a micro-LED 1000 having slanted non-vertical sidewalls 102 and a LIL 1020, compared to a curve 3004 of light extraction from a Lambertian LED having the same total extraction. The micro-LED 1000 has higher extraction than a Lambertian LED at all angles. For instance, the micro-LED 1000 extracts 25% more light in a 30 degree cone than a Lambertian LED. FIG. 31 shows a similar comparison of a curve 3102 for which gamma=72.5 degrees versus a curve 3104 of light extraction from a Lambertian LED having the same total extraction. The embodiment in which gamma=75 degrees extracts 35% more light in a 30 degree cone than a Lambertian LED. Some embodiments have a total light extraction Cex and a light extraction Cex2 in a cone of angle 10 deg (or 20 deg, 30 deg, 40 deg, 50 deg), such that Cex2/ Cex is at least 20% (or 30%, 40%, 50%) higher than if the emitter were Lambertian.

FIG. 32 is a graph 3200 illustrating light extraction as a function of pixel size of a micro-LED in accordance with some embodiments. For clarity, previous figures in this disclosure assumed a base pixel radius of 1.5 um. In FIG. 32, several configurations are considered, and for each configuration Cex and Cex30 are calculated. The distance d between the quantum well (QW) and the bottom mirror 114 is 130 nm. In a first case, for a micro-LED without a LIL, and having a mesa with gamma=35 degrees, a curve 3208 showing Cex and a curve 3203 showing Cex30 decrease substantially with increasing radius, because a larger mesa lets more large-angle light escape away from the pixel. In a second case, for a micro-LED with a LIL having theta50=50 degrees and having a mesa with gamma=35 degrees, a curve 3210 showing Cex and a curve 3204 showing Cex30 are increased and are less dependent on the mesa base radius. This is because the LIL reflects large-angle light, so that the mesa sidewall can extract it. In a third case, for a micro-LED with a LIL having theta50=50 degrees and a mesa with gamma=55 degrees, a curve 3212 showing Cex and a curve 3206 showing Cex30 are further increased and are nearly independent of the mesa base radius.

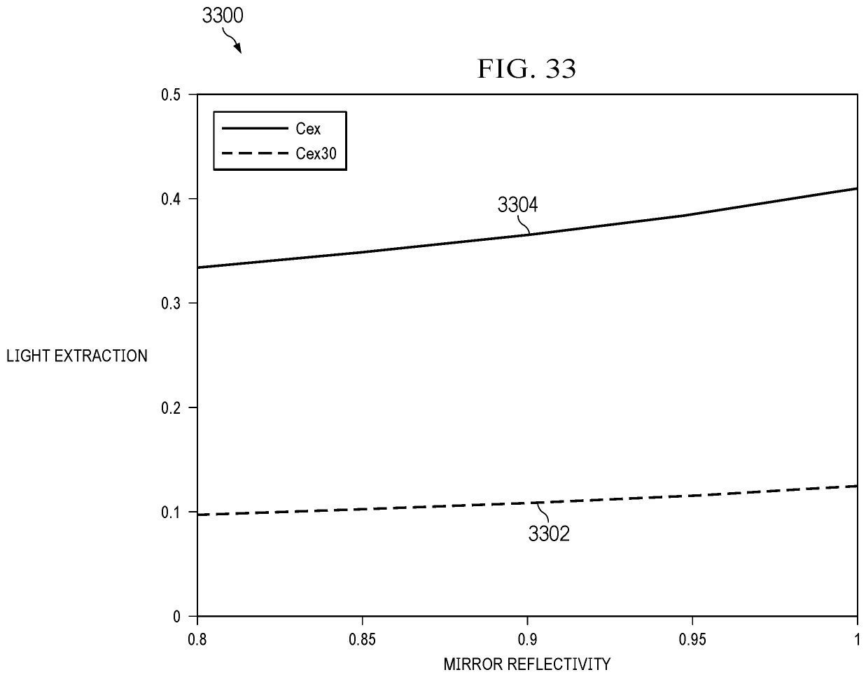

FIG. 33 is graph 3300 illustrating light extraction as a function of mirror reflectivity of a micro-LED in accordance with some embodiments. In the illustrated example, the pixel has d=130 nm, an LIL with theta50=50 degrees, and a sidewall with gamma=35 degrees. The reflectivity is varied for the bottom mirror 114 and sidewall mirrors. Higher reflectivity leads to higher Cex, as illustrated in curve 3304, and Cex30, as illustrated in curve 3302. Some embodiments have a bottom mirror and/or a sidewall mirror with a normal-incidence reflectivity (at the wavelength of emission of the LED) which is at least 80% (or 85%, 90%, 95%).

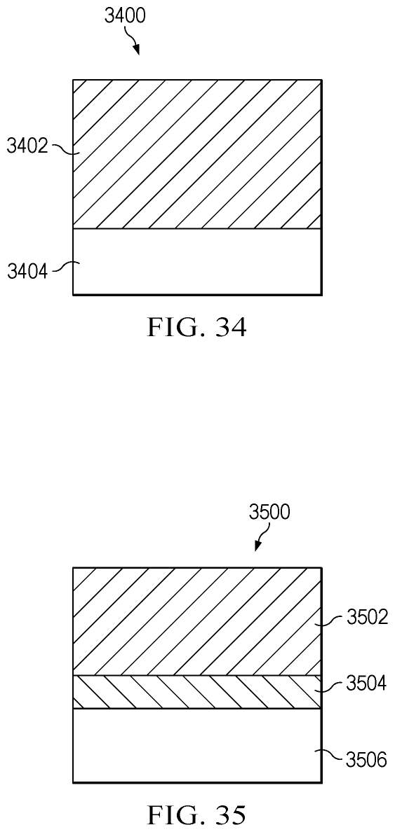

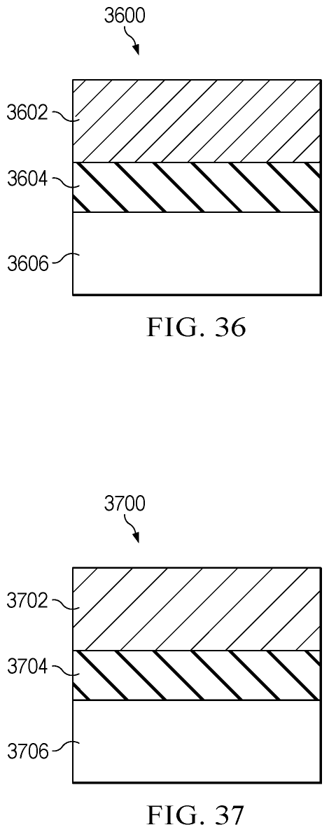

FIGS. 34-37 are block diagrams of mirror architectures for a micro-LED in accordance with some embodiments. FIG. 34 shows a block diagram 3400 of a mirror architecture having a thick metal 3402 over a semiconductor 3404. FIG. 35 shows a block diagram 3500 of a mirror architecture having a multilayer metal stack, with a thin metal 3504 and a thick metal 3502 over a semiconductor 3506; the thin metal may be thinner than 10nm (or 5 nm, 2 nm, 1 nm, 0.5 nm, 0.2 nm). Other stacks may be used with varying metal thicknesses, to improve reflectivity, adhesion, contact resistance, stress, and other properties known in the art. FIG. 36 shows a block diagram 3600 of a mirror architecture having a stack with a dielectric layer 3604 and a thick metal 3602 over a semiconductor 3606. FIG. 37 shows a block diagram 3700 of a mirror architecture having a transparent conductor 3704 and a thick metal 3702 over a semiconductor 3706.

In some embodiments, metals used for the thick metal 3402, 3502, 3602, 3702 and the thin metal 3504 include Al, Ag, Au, Ni, Ti, Mo, Sn and other metals. Dielectrics used for the dielectric layer 3604 include SiOx (eg SiO2), SiN, AlOx (eg Al2O3), TaOx (eg Ta2O5), TiOx (eg TiO2), NbOx, and other dielectrics known in the art. Transparent conductors 3704 may include ITO, ZnO, and other materials known in the art. Mirrors may include DBR-type mirrors (also called dichroic mirrors), such as stacks of dielectrics with low and high indices. A standard DBR has low- and high-index layers with respective thicknesses lambda/4n. In some embodiments, the mirror does not have any metal layer. The mirror may for instance be provided by a semiconductor/air interface, or a semiconductor/dielectric/air interface.

In addition to half-cavity effects (caused by interference from a mirror), some embodiments make use of full-cavity effect (caused by interference from a mirror and from a LIL) to improve light extraction and directionality. This is especially true if the distance between the LIL and the mirror is thin, e.g., less than 1 um (or 500 nm, 300 nm).

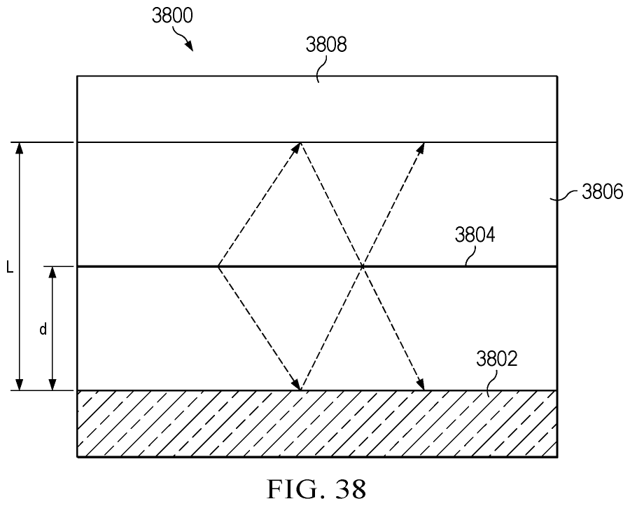

FIGS. 38-40 illustrate cavity effects. FIG. 38 is a block diagram of a cavity geometry of a micro-LED in accordance with some embodiments. The light-emitting layer 3804 is in a semiconductor matrix 3806. The distance from the light-emitting layer 3804 to the mirror 3802 is d. The cavity thickness between the mirror 3802 and the LIL 3808 is L. Light emitted from the light-emitting layer 3804 can be reflected by the mirror 3802 and the LIL 3808, causing cavity effects.

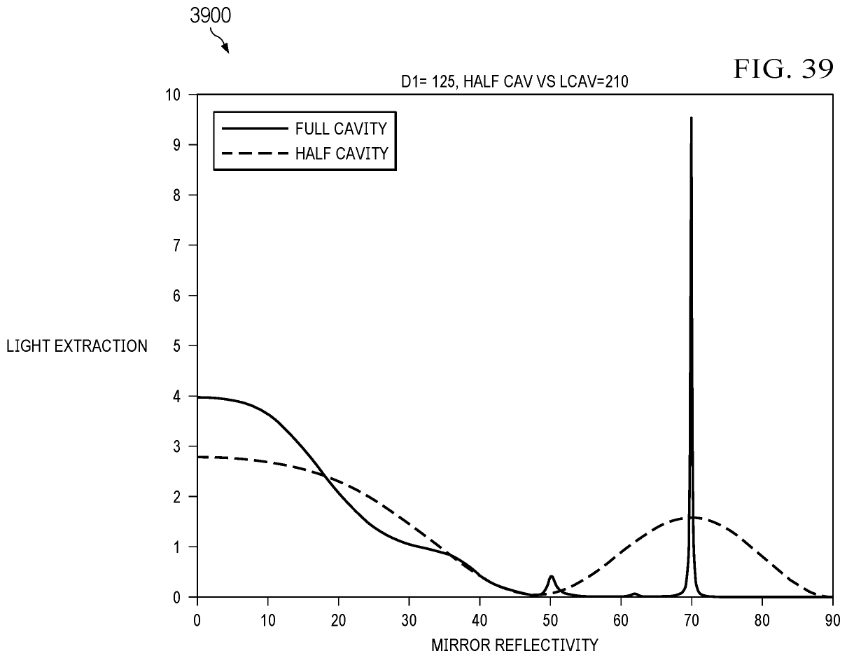

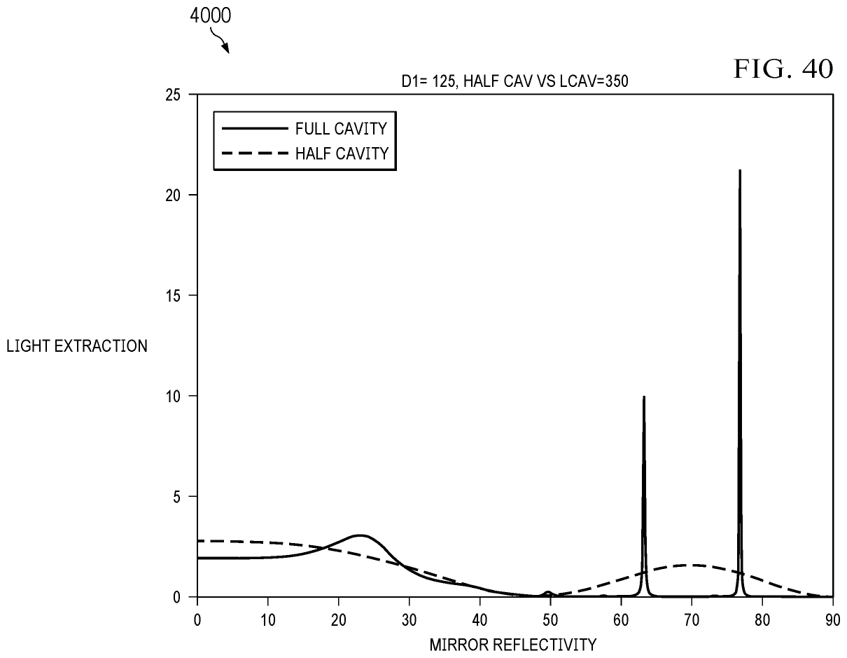

FIG. 39 is an emission diagram 3900 comparing a half-cavity without a low-index layer and a full cavity with a low-index layer in accordance with some embodiments. In the illustrated example, d=125 nm and L=210 nm. The full cavity leads to a guided mode (near 70 degrees), which channels the light emitted in the range 50-90 degrees.

FIG. 40 is an emission diagram 4000 comparing a half-cavity without a low-index layer and a full cavity with a low-index layer in accordance with some embodiments. In the illustrated example, d=125 nm and L=350 nm. Here, the full cavity leads to two guided modes (near 63 degrees and 78 degrees), which channels the light emitted in the range 50-90 degrees. By configuring the cavity dimensions, light can be emitted in desired directions, and can then be extracted with an appropriate LED geometry (e.g., slanted sidewalls).

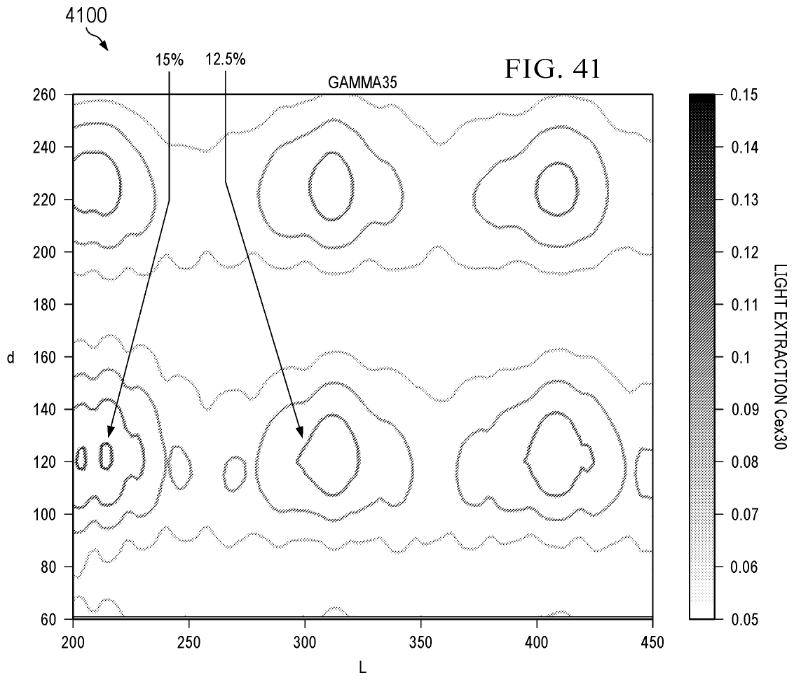

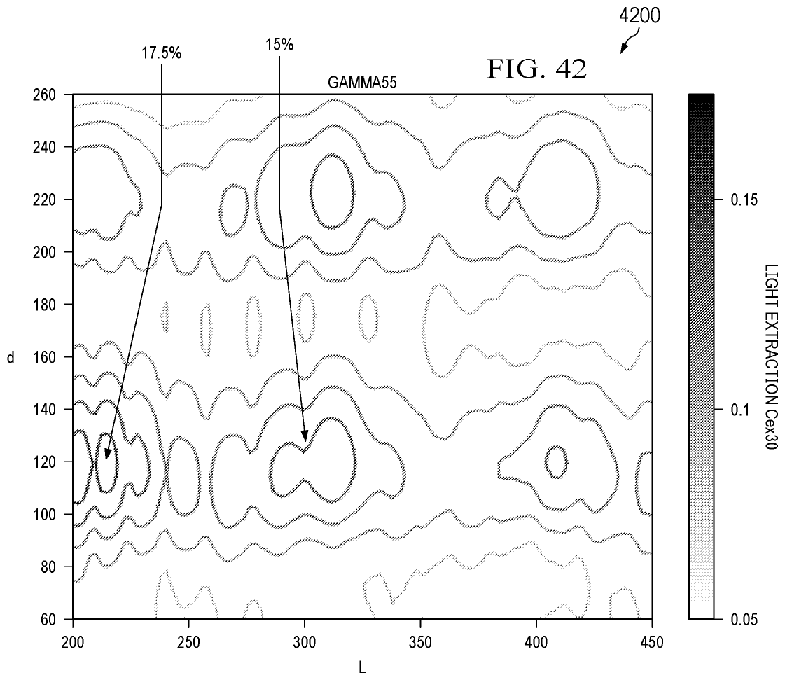

FIGS. 41 and 42 are graphs 4100, 4200 illustrating light extraction light under various cavity parameters of a micro-LED in accordance with some embodiments. FIGS. 41 and 42 show the light extraction in 30 degrees (Cex30) when the parameters of the cavity (L and d) are varied. FIG. 41 considers a slanted angle gamma=35 degrees. By configuring the cavity parameters, Cex30 can be above 10% or 12.5% or 15%. FIG. 42 considers a slanted angle gamma=55 degrees. By configuring the cavity parameters, Cex30 can be above 10% or 12.5% or 15% or 17.5%.

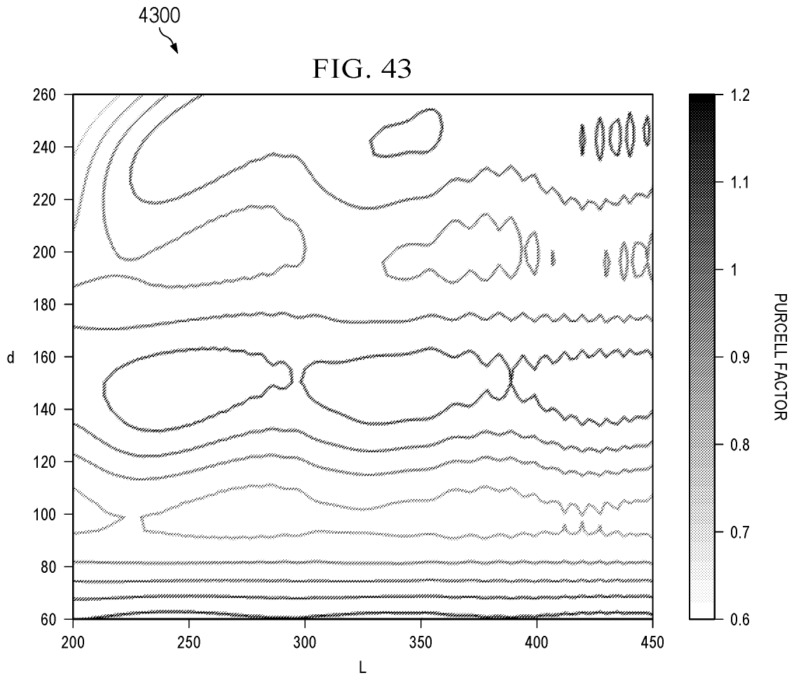

FIG. 43 is a graph 4300 illustrating a Purcell factor Fp corresponding to FIG. 42. A Purcell factor indicates an enhancement of a quantum system's spontaneous emission rate by its environment. A high Fp may be desirable and may be achieved by properly configuring the cavity. Some embodiments provide Fp above 1 (or 1.1, 1.2). Some embodiments provide a light extraction above a predetermined level together with a value of Fp above a predetermined level.

In previous calculations, where an Al bottom mirror was considered, light extraction was improved for d˜120-130 nm. The optimal value of d depends on the phase shift of the metal mirror, which is determined by the refractive indices of the semiconductor and of the metal. Based on the present teachings, one skilled in the art will understand how to configure the display (including configuring the semiconductor layer thicknesses in conjunction with the index of the metal mirror) to achieve an optical interference which improves the emission from the display.

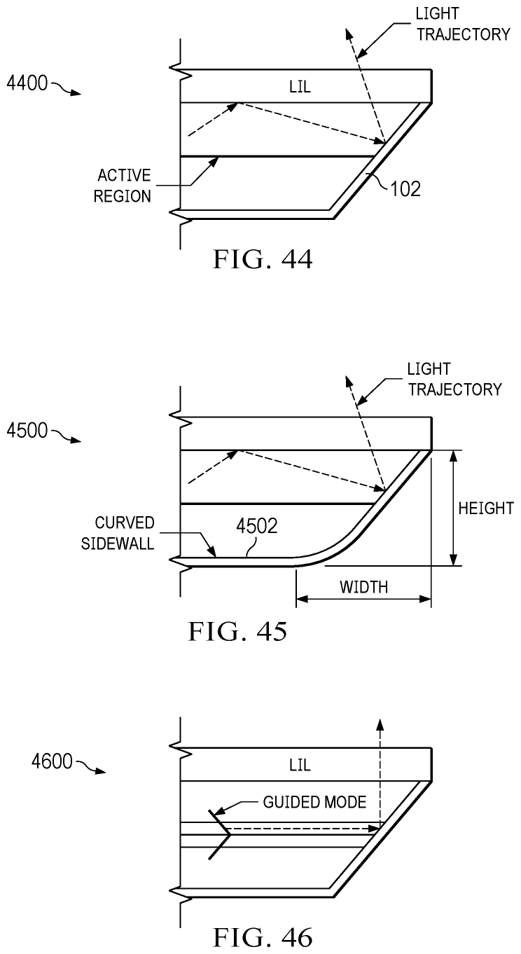

FIGS. 44, 45, and 46 are block diagrams illustrating possible geometries for micro-LED mesas 4400, 4500, 4600 in accordance with some embodiments. Each of the micro-LED mesas 4400, 4500, 4600 have non-vertical sidewalls 102, where vertical refers to the direction perpendicular to the display's output facet). FIG. 44 shows a slanted sidewall 102 with a constant angle gamma, which corresponds to examples discussed previously herein. A light trajectory with a high angle is extracted by the slanted sidewall 102. FIG. 45 shows a curved sidewall 4502; other shapes with a non-constant angle can also be used, including geometries where a part of the sidewall 4502 is vertical and a part of the sidewall 4502 is non-vertical. A light trajectory with a high angle is extracted by the curved sidewall 4502. Given the present teachings, one skilled in the art will understand how to configure the shape of the sidewall 4502 to improve emission. FIG. 46 illustrates a configuration in which the layers around the active region form a waveguide. This may happen, for example, if the active region has a sufficient number of quantum wells, or if the quantum wells are embedded in a high-index cladding. In the illustrated example, a guided mode travels laterally and is extracted by the slanted sidewall upon reaching the mesa edge.

In some embodiments where light is guided, the epitaxial structure is configured to affect the guiding properties. In some embodiments, a waveguide surrounds the active region. The waveguide may have a thickness less than 1 um (or 500 nm, 200 nm). The waveguide may comprise InGaN materials with sufficient composition to cause guiding (e.g., an InGaN cladding and InGaN quantum wells). At least 10% (or 20%, 50%) of the light emitted by the active region may be guided light.

The guided mode may be characterized by its vertical extent, which is commensurate with the thickness of the waveguide. The guided mode may have a vertical extent of at least 50 nm (or 100 nm), and less than 1 um (or 500 nm, 200 nm). The guided mode may be propagative (i.e., have an oscillating behavior) in layers forming the waveguide, and decay exponentially in lower-index layers surrounding the waveguide. For instance, the waveguide may include an InGaN active region and InGaN layers surrounding the active region and acting as a cladding; the waveguide may be surrounded by GaN layers (or InGaN layers with a lower In content than the cladding layers) in which the guided mode is evanescent.

Non-vertical sidewall shapes may be imparted by a variety of techniques. One may grow a semiconductor mesa with a non-vertical sidewall (for instance, a semi-polar sidewall). One may saw the semiconductor (e.g., with a blade). One may use laser ablation. One may use a wet etch (such as a chemical etch, photo-chemical etch, electro-chemical etch, photo-electro-chemical etch); such etches may favor specific crystal planes (such as a semi-polar plane). Wet etchants may include acidic and alkaline etchants, H3PO4, KOH, HF. Wet etchants may be applied at a temperature above room temperature (at least 50 C or 100 C or 150 C); they may be maintained at a moderate temperature (less than 100 C, 80 C, 60 C) to avoid defect decoration. One may use a dry etch (including RIE or ICP). Materials (such as dielectrics) may be deposited on a sidewall to impart it a shape, or a non-vertical profile. Some of these techniques may be combined; for instance, a mesa may be dry etched, then wet-etched, then covered with a dielectric material.

Non-vertical sidewalls do not necessarily have a constant slant angle (as shown in FIG. 45). In general, the non-vertical sidewall may be characterized by an average angle gamma, defined by the width w and the height h of the non-vertical region according to tan(gamma)=w/h. Some embodiments are characterized by an average angle in a range 30-40 deg, or in a range 50-60 deg.

### Vicinity

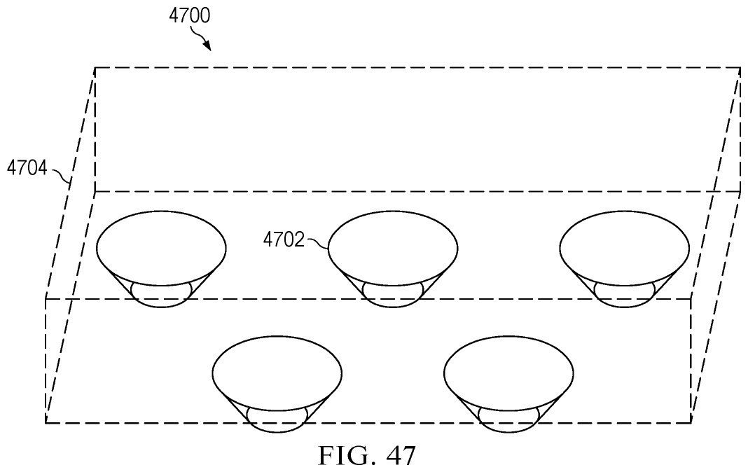

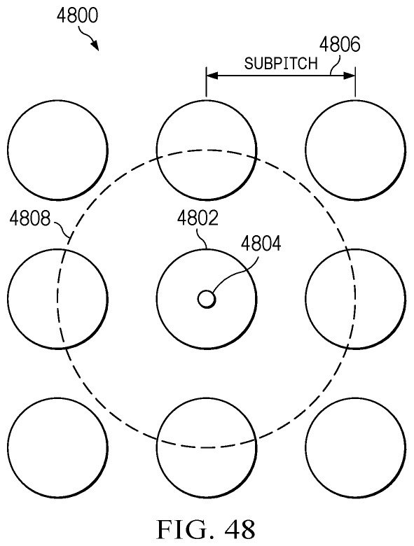

FIGS. 47 and 48 illustrate various views of a micro-LED array. FIG. 47 shows an isometric view of a micro-LED array 4700 with several subpixels 4702 having slanted (non-vertical) sidewalls, and a semiconductor member 4704 joining the subpixels 4702. In some embodiments, the subpixels 4702 are grown epitaxially on the semiconductor member. FIG. 48 shows a top view of an array 4800 of subpixels 4802, separated by a subpitch 4806. The subpixels 4802 may be arranged in groups to form pixels (for instance a red, green, and blue subpixels for a pixel). A vicinity 4808 of a subpixel 4802 is shown. As taught herein, light emitted by the subpixel 4802 may be substantially extracted in the vicinity 4808. Here the subpixel 4802 is circular, and the vicinity 4808 is circular with the same center 4804 as the subpixel 4802. The vicinity 4808 may be small enough to provide a good display resolution. In some embodiments, the diameter of the vicinity 4808 (or more generally, a characteristic lateral dimension of the vicinity 4808) is substantially similar to the subpitch 4806; it may be less than 2 (or 3, 4, 5, 10) times the pitch.

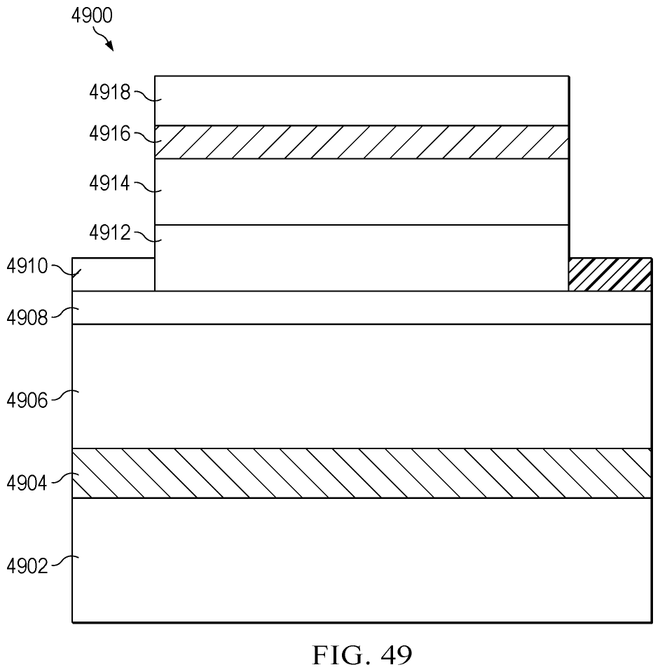

FIG. 49 illustrates a semiconductor stack 4900 of a micro-LED in accordance with some embodiments. For clarity, the semiconductor stack 4900 is shown in the growth direction; whereas in some other figures herein, the stack is flipped, and the growth substrate is removed. In the illustrated example, materials are listed the case of a III-Nitride stack, though other material systems are also possible. The semiconductor stack 4900 has a growth substrate 4902, such as a sapphire, silicon, or a bulk III-Nitride layer. An initiation layer 4904 is grown on the growth substrate 4902. The initiation layer 4904 is a 3-dimensional nucleation III-Nitride layer, or a dielectric mask (e.g., SiN or SiO2 or AlOx with sub-micron openings) with III-Nitride growth over the substrate in some embodiments; alternatively, the substrate interface may be patterned (e.g., patterned sapphire or silicon), and the initiation layer 4904 may be a Ill-Nitride layer which recovers a planar morphology. A buffer layer 4906 is then grown; the buffer layer 4906 may be n-doped; it may be GaN or InGaN or AlInGaN, or a multilayer of III-nitride materials. The buffer layer 4906 may have a substantially planar top surface. A low-index layer (LIL) 4908 is then grown. The LIL 4908 may be AlInN and may be substantially lattice-matched to the buffer layers; the LIL 4908 may be n-doped. A mask 4910 such as a dielectric mask is formed on the LIL 4908. Several LED layers are then grown selectively in the aperture of the mask. They include a first n-layer 4912, for instance In(x1)Ga(1-x1)N with a first In concentration x1, a second n-layer 4914, for instance In(x2)Ga(1-x2)N with a second In concentration x2, an active region 4916 (with In(x3)Ga(1-x3)N quantum wells and In(x4)Ga(1-x4)N barrier), a third p-layer 4918 (which may include an electron blocking layer, a p-layer and a p++ contact layer).

The mesa of FIG. 49 is shown with vertical sidewalls for simplicity. However, a non-vertical shape may be imparted, as disclosed herein. Variations in the details of the epi stack are possible—some layers may be added, omitted, or moved to different locations. For instance, the LIL 4908 may be grown inside the mesa rather than on the buffer 4906; or it may be covered by other planar layers before the mesas are formed.

The LED structure may be doped as known in the art. In the case of III-Nitride, appropriate n-dopants include Si, O, Ge; appropriate p-dopants include Mg. Other doping schemes, such as tunnel junctions and polarization-induced doping, may be used. Doping spikes may be used at heterointerfaces to counter band discontinuities and/or to screen polarization fields. For instance, at an interface between GaN and AlInN, a doping spike (or, a high doping level above 1E19 cm−3 or 1E20 cm−3) may be used.

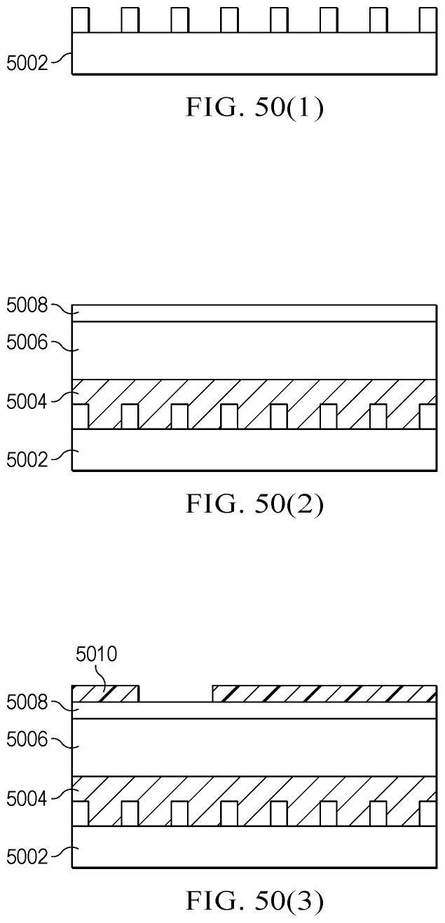

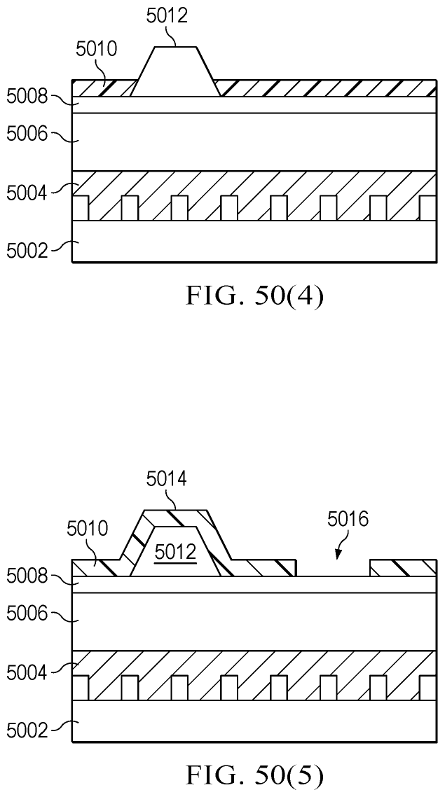

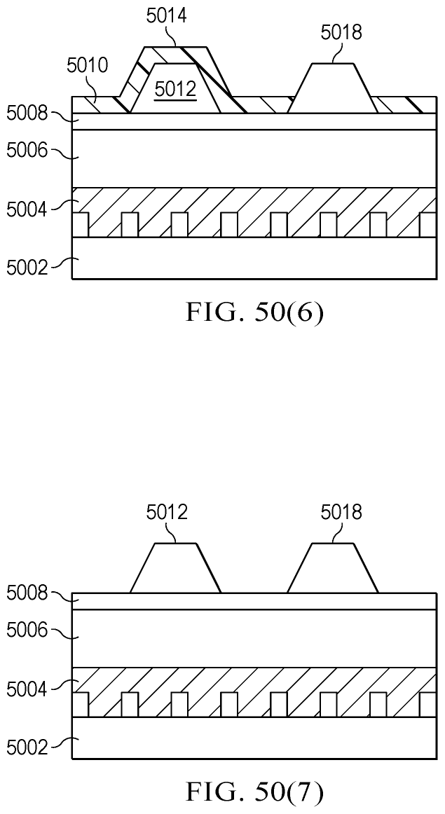

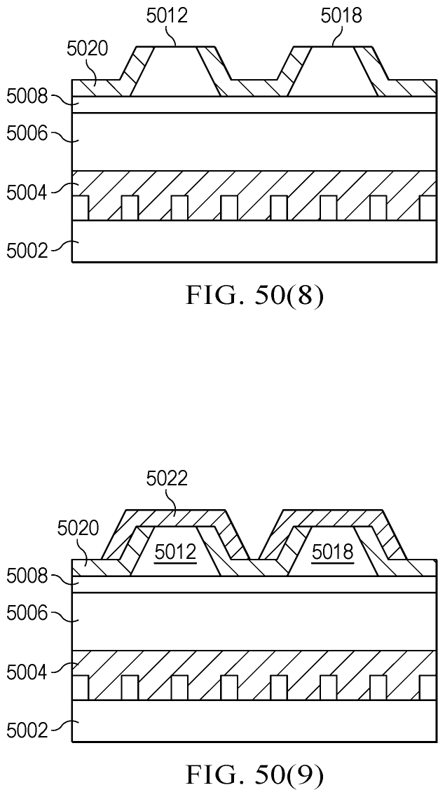

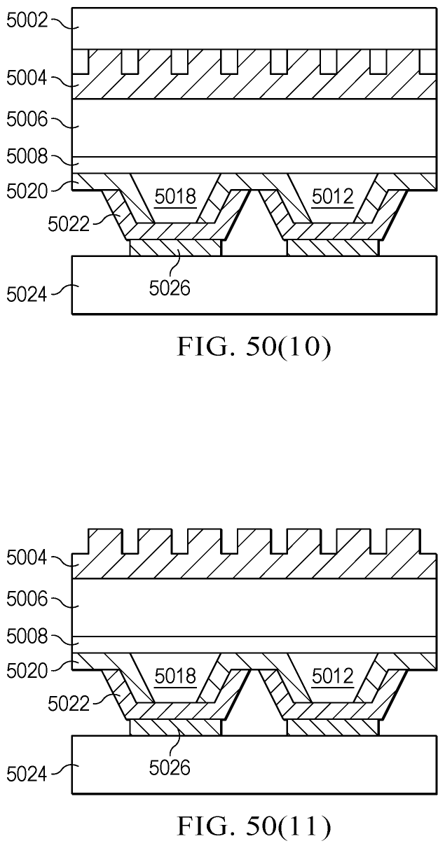

FIGS. 50(1)-(11) illustrate a fabrication flow for a micro-LED in accordance with some embodiments. In FIG. 50(1), a substrate 5002 (e.g., nano-patterned Si or Sapphire) is provided. In FIG. 50(2), an initiation layer 5004 and a buffer 5006 (e.g., GaN) are grown, followed by a low-index layer 5008. In FIG. 50(3), a dielectric mask 5010 (e.g., SiN, SiOx, AlOx) is formed, with an opening. In FIG. 50(4), a first micro-LED 5012 is grown in the opening, for instance by selective epitaxy. In FIG. 50(5), the first micro-LED 5012 is covered with a second mask 5014, and a second opening 5016 is formed. In FIG. 50(6), a second micro-LED 5018 is grown. It should be clear that, although only two micro-LEDs 5012, 5018 are shown, arrays of first and second micro-LEDs are formed in some embodiments. Using similar steps, additional micro-LEDs are grown. In FIG. 50(7), the growth masks 5010, 5014 are removed. In FIG. 50(8), a passivation layer 5020 (e.g., a dielectric such as AlOx) is formed on the sidewalls of the mesas. In FIG. 50(9), p-contacts 5022 are formed on the mesas and the sidewalls. The p-contacts 5022 are in direct contact with the top of the mesa, providing an electrical contact. On the sidewalls of the mesa, the p-contact 5022 is separated from the semiconductor by the passivation layer 5020 so that is provides reflectivity without making an electrical contact. In FIG. 50(10), after the front-end processing described with respect to FIGS. 50(1)-(9), the LED wafer is inverted and bonded to a backplane 5024 having backplane contacts 5026. The backplane 5024 is a CMOS backplane in some embodiments. In some embodiments, the backplane 5024 is silicon-based and includes driver circuitry to drive the pixels of a display. The bonding may be a hybrid wafer-wafer bonding using a damascene process (dielectric layers typical of a damascene process are not shown for simplicity). In FIG. 50(11), the growth substrate 5002 is removed. Several of the steps of FIGS. 50(1)-(11) necessitate sub-steps (such as lithography, lift-off and etching steps) known in the art, which are not shown.

A substrate (e.g., sapphire, silicon, GaOx, SiC, GaN) may have a planar or a textured surface. A textured surface may have non-planar features that are periodic, quasi-periodic, aperiodic, random. Features may have vertical and/or lateral dimensions than are micron-scale (e.g., 1 to 10 um, or less than 10 um, less than 5 um) or nano-scale (e.g., 100 nm to 1 um, or less than 1 um). Lateral dimensions include the size of a feature, and the characteristic distance, or pitch, between features. In some embodiments, a characteristic lateral dimension of a feature is less than the pitch of a subpixel. In some embodiments, a substrate has periodic features with a pitch which is less than 50% (less than 20%, 10%) of the subpixel pitch.

Some embodiments are characterized by an optically-averaged refractive index around a layer. The optically-averaged refractive index is defined as the average of indices, weighed by thicknesses, for layer within +/−half an optical wavelength from the layer center. For instance, for a micro-LED emitting light at an optical wavelength 600 nm, the optically-averaged average index is averaged over +/−300 nm from the layer center. This can be relevant to describe the index seen, e.g., by a guided mode. For a layer with a varying composition (e.g., graded In or Al content), a material-averaged refractive index may be defined by averaging the index along the layer.

An LIL may be an Al-containing layer or stack of layers. The LIL may have a lattice constant selected to reduce strain. For instance, it may be lattice-matched to other layers (including to a GaN buffer or to an InGaN-containing layer). The LIL may be AlGaN, AlInN, AlInGaN. The LIL may be grown at a relatively low temperature (e.g., less than 1000 C, 900 C, 850 C, 825 C, 800 C). It may be grown at a relatively high pressure (e.g., above 0.2 atm, 0.5 atm, 0.8 atm, 1 atm, 1.5 atm, 2 atm). The growth may be interrupted during a transition between two materials (such as a GaN/AlInN interface) while the carrier gases are switched, and the temperature is ramped (e.g., T>1000 C for GaN and T<900 C for AlInN). Ge doping is employed in some embodiments to obtain high n-doping (e.g., free carrier concentration above 1E19cm−3, 5E19cm−3, 1E20cm−2, 2E20cm−3) while maintaining a good morphology (for example, a surface with an RMS roughness less than 3 nm or 1 nm or 0.5 nm or 0.2 nm, which may be measured by AFM). In-situ monitoring (e.g., wafer bow measurements, temperature/pyrometer measurements, in-situ XRD) may be employed to measure strain. In some embodiments, a LIL is substantially lattice-matched to surrounding layers (such as a GaN buffer). The LIL's equilibrium in-plane lattice constant may be within 5E-3 nm (or 1E-3 nm, 5E-4 nm, 1E-4 nm) of the lattice constant of the layer over which it is grown.

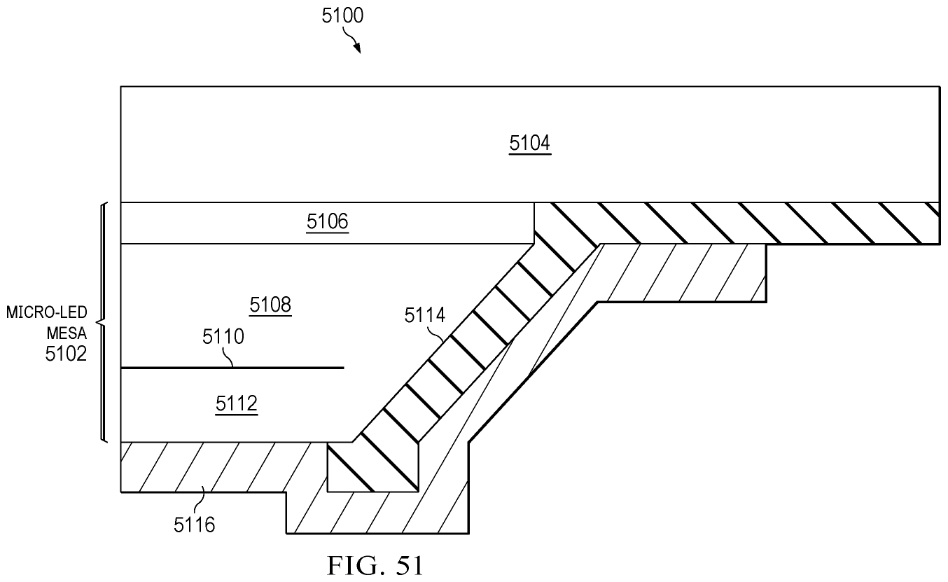

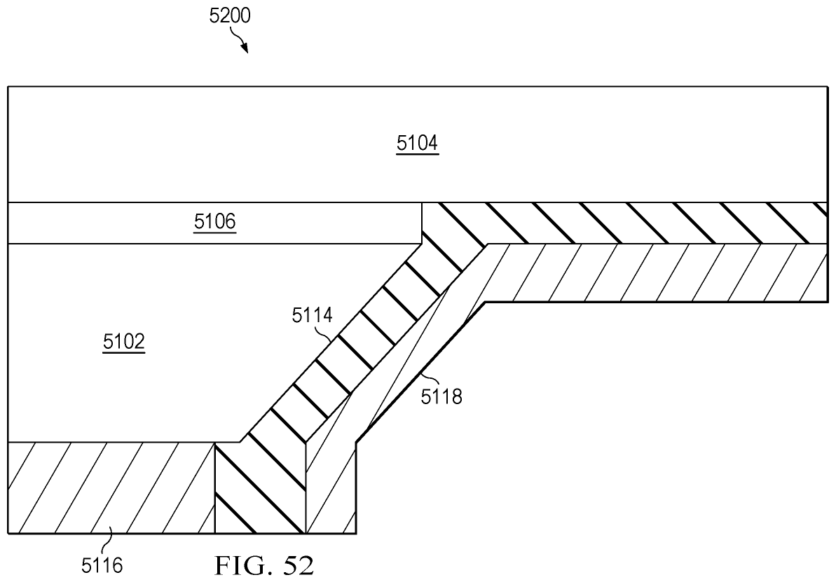

FIGS. 51 and 52 are block diagrams 5100, 5200 illustrating layers around a micro-LED mesa in accordance with some embodiments. In FIG. 51, a micro-LED mesa 5102 is grown on a semiconductor member 5104 (the figure shows the epitaxial upside down, with the mesa at the bottom). The micro-LED mesa 5102 has an n-doped low index layer 5106, n-doped semiconductor material 5108, an active region 5110, and p-doped semiconductor material 5112. A dielectric layer 5114 is formed on the sidewalls of the micro-LED mesa 5102, and on the planar region in-between mesas. The dielectric layer 5114 provides electrical insulation. A metal layer 5116 is formed on top of the p-type semiconductor 5112 and on part of the dielectric 5114. The metal layer 5116 serves both as a p-contact and as a reflector on the slanted sidewall.

In FIG. 52, two metal portions 5116, 5118 are present. The first metal portion 5116 acts as a p-metal. The second metal portion 5118 acts as a reflector on the non-vertical sidewall. The dielectric member 5114 in-between the first metal portion 5116 and the second metal portion 5118 provides electrical separation. In this case, two different metals may be used. For example, the p-metal 5116 may be selected to provide a good electrical contact, and the reflector metal 5118 may be selected for maximal reflectivity (e.g., Ag, Al, Au). The shapes of the features illustrated in FIGS. 51 and 52 may be obtained by conventional fabrication techniques, including material evaporation (by e-beam, ALD, sputtering, thermal evaporation), lithography, grinding/polishing/lapping.

In other implementations, the active region 5110 may be grown on the sidewalls of the micro-LED mesa 5102 (for instance, a mesa of III-nitride material may be grown with slanted semi-polar planes may be grown, and with quantum wells along the sidewalls). In some cases, active region material is grown both on the sidewalls and on the planar region of the mesa (typically, a c-plane in the case of a III-nitride). In some cases, p-GaN is grown on the sidewalls and/or on the planar region. Electrical contact may be then formed to the planar region, to the sidewall region, or both. Accordingly, electrical injection may occur at the planar region, at the sidewall region, or both. Similar to FIGS. 51 and 52, various combinations of passivation layers and metal layers may provide selective injection of the planar region or the sidewall region. For instance, a passivation layer may be formed on and around the planar region to prevent electrical injection there. A metal may then be deposited on the sidewall region (and possibly also on top of the passivation layer) to form a contact and provide electrical injection to the sidewall. As taught herein, and similar to the case of a planar active region, the geometry of the micro-LED may be configured to enhance light extraction if light is emitted from a non-vertical active region along the mesa sidewalls—this includes configuring the angle of the sidewalls, the thickness of the p-GaN, the optical distance between the active region and the bottom mirror.

Semi-polar planes include (20-21), (20-31), (20-32), (20-2-1), (20-3-1), (20-3-2), and other planes known in the art. Semi-polar planes may provide emission of blue and/or green and/or red light. The plane may be selected to provide a desired angle and improve light extraction. Some configurations combine mesas having semi-polar QWs and mesas having polar (+c or −c plane) LEDs; these mesas may correspond to different emission wavelengths. Some embodiments have significant light guiding around the active region, for instance due to the presence of one or several high-index layers acting as cladding layers.

Some embodiments include (in order of growth): a substrate, a planar semiconductor buffer layer (comprising, e.g., GaN, AlN, AlGaN, InGaN, AlInN or multilayers of these materials), and a mesa. The mesa has multiple layers, including several In-containing layers and an InGaN-containing active region. The In-containing layers and the active region form a waveguide in some embodiments, such that some of the light emitted by the active region is emitted into a guided mode supported by the waveguide. The guided mode has an effective index higher than the index of GaN and does not propagate in the buffer layer.

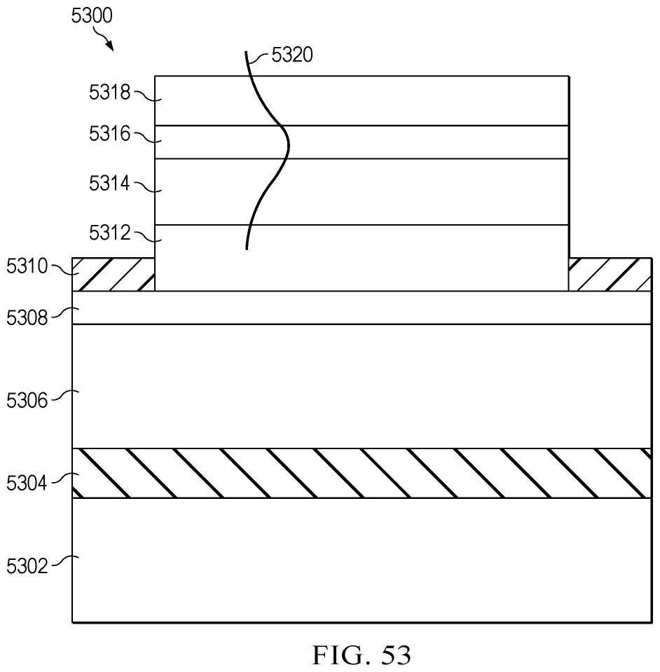

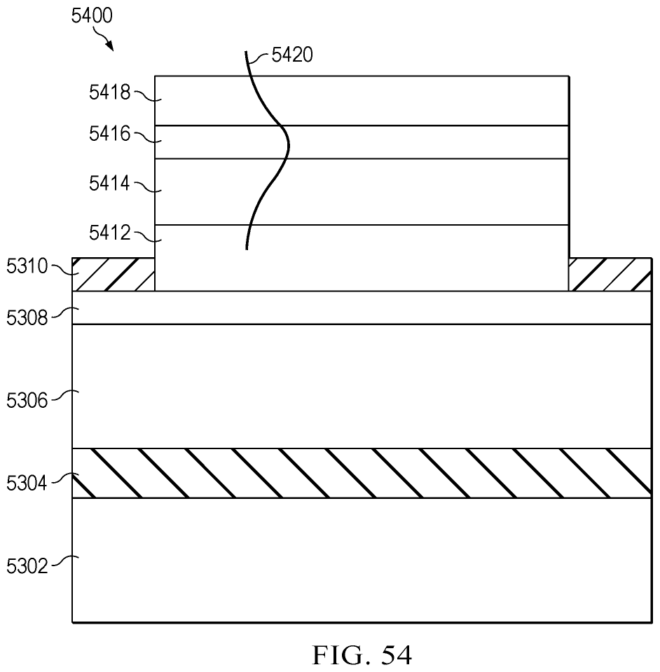

FIGS. 53 and 54 are block diagrams of epitaxial structures 5300, 5400 of a micro-LED in accordance with some embodiments. In FIG. 53, the epitaxial structure 5300 has an Si substrate 5302, an AIN initiation layer 5304, a GaN buffer layer 5306, and AlInN low index layer 5308. A mask 5310 with openings enables selective area epitaxy of mesas to form a micro-LED. The micro-LED has a GaN layer 5312, an InGaN n-region 5314 characterized by In concentration x1, an InGaN active region 5316 characterized by In concentration x2, an InGaN p-region 5318 characterized by In concentration x3. The values of x1, x2, x3 are configured such that a guided mode 5320 is supported by the active region and neighboring layers, at the emission wavelength of the active region. The guided mode 5320 does not propagate in the GaN layer 5312 of the mesa—in other words, its effective index is lower than the index of GaN. In some embodiments, only one mode is supported at the emission wavelength of the active region. In some embodiments, at least 5% (or 10%, 20%) of the light emitted by the active region is emitted in the guided mode. In some embodiments, the device is configured such that this guided mode 5320 is substantially extracted—for instance, by configuring the shape of the sidewalls (i.e., non-vertical shape, presence of a reflective layer). In some embodiments, at least 10% (or 25%, 50%, 75%) of the power emitted in the guided mode is extracted.

Although FIG. 53 shows uniform InGaN regions 5314, 5316, 5318, one skilled in the art will realize that multi-layers may also be used. For instance, the InGaN n-region 5314 may be a superlattice (e.g. GaN/InGaN or InGaN/InGaN)—in this case, x1 is the average In composition over the thickness of the superlattice. More generally, for a multilayer, x1 may be defined as the average over the thickness of the region. Likewise, the InGaN p-region 5318 may comprise multiple layers, such as an electron-blocking layer (which may be made of InGaN, GaN or AlGaN), an InGaN p layer and an InGaN p++ layer.

In some embodiments, x1>2% (or 5%, 10%, 15%). In some embodiments, x2>15% (or 20%, 30%, 40%, 50%, 60%). In some embodiments, x3>2% (or 5%, 10%, 15%). In some embodiments, x1>2% and x2>x1+5%. In some embodiments, x3>2% and x2>x3+5%.

FIG. 54 is similar to FIG. 53, but includes two InGaN n-regions 5412, 5414, with In compositions x1_1 and 1_2. In some embodiments, x1_1<x1_2. Mode generally, in some embodiments, the In composition gradually increases along the growth direction. This may gradually facilitate releasing the strain in the material. The micro-LED further has an InGaN active region 5416 characterized by In concentration x3, and an InGaN p-region 5418 characterized by In concentration x4. The values of x3, x4 are configured such that a guided mode 5420 is supported by the active region and neighboring layers, at the emission wavelength of the active region.

In some embodiments, certain aspects of the techniques described above may implemented by one or more processors of a processing system executing software. The software comprises one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

A computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

1. A micro light emitting diode (micro-LED) device comprising a lateral dimension less than 20 microns, comprising:
a light-emitting layer; an output facet;
an optical interface parallel to the light-emitting layer; and
a non-vertical sidewall forming an angle γ with respect to a normal of the light-emitting light emitting-layer, wherein the light-emitting layer emits light comprising a first light in a first trajectory that escapes the micro-LED through the output facet without substantially reflecting off the optical interface and a second light in a second trajectory that reflects off the optical interface and the non-vertical sidewall and escapes through the output facet.

2. The micro-LED device of claim 1, wherein the optical interface is an interface between a high-index semiconductor and a low-index semiconductor.

3. The micro-LED device of claim 1, wherein the second light comprises at least 10% of the light emitted by the light emitting layer.

4. The micro-LED device of claim 1, wherein the angle γ is selected to reflect the second light in a direction substantially perpendicular to the output facet.

5. The micro-LED device of claim 1, wherein at least 50% of an optical power emitted in the second light escapes through the output facet.

6. The micro-LED device of claim 1, wherein the second light reflects off the optical interface through a total internal reflection.

7. (canceled)

8. (canceled)

9. (canceled)

10. (canceled)

11. A micro light emitting diode (micro-LED) device having a lateral dimension less than 20 um, comprising:
a light emitting layer to emit light having a wavelength; an output facet;
a mirror parallel to the light emitting layer and in optical proximity to the light emitting layer; and
a non-vertical sidewall, wherein
the light emitting layer and the mirror are jointly configured such that the light emitting layer preferentially emits light in a trajectory that reflects off the mirror and the non-vertical sidewall to escape through the output facet.

12. The micro-LED of claim 11, wherein a distance between the mirror and the light emitting layer is less than three times the wavelength.

13. The micro-LED of claim 11, wherein a distance between the mirror and the light emitting layer is selected to cause a constructive optical interference for the light emitted in the trajectory.

14. The micro-LED of claim 11, wherein at least 10% of a total emission by the light emitting layer is emitted in the trajectory.

15. The micro-LED of claim 11, wherein the light emitted in the trajectory has an enhancement factor of at least 2.5 compared to a light that would be emitted by the light emitting layer in a homogeneous material.

16. The micro-LED of claim 11, wherein the light emitting layer emits a second light in a second trajectory that is not substantially extracted from the micro-LED, with an enhancement factor less than 0.5.

17. A display, comprising:
a semiconductor member having a display output surface to emit a display light in a vertical direction; and
a plurality of micro-light emitting diodes (micro-LEDs) formed epitaxially on the semiconductor member, at least one micro-LED comprising:
non-vertical sidewalls;
a light-emitting layer;
a mirror formed on a facet of the micro-LED opposite the semiconductor member; and
a low-index epitaxial layer located in the micro-LED or in the semiconductor member,
wherein the low-index epitaxial layer and the mirror are configured such that a light emitted by the light-emitting layer reflects at least once off the low-index epitaxial layer and once off the mirror before being emitted through the output surface.

18. The display of claim 17, wherein the light is emitted by the light-emitting layer at an angle greater than 60 degrees with respect to a normal of the output surface.

19. The display of claim 17, wherein a difference between a first index of refraction of the low-index epitaxial layer and a second index of refraction of the semiconductor member is at least 0.2.

20. The display of claim 17, wherein the reflection off the low-index epitaxial layer is a total internal reflection.

21. The display of claim 17, wherein the light further reflects off one of the non-vertical sidewalls before being emitted through the output surface.

22. The display of claim 17, wherein at least 50% of the light emitted by the light-emitting layer is extracted from the micro-LED.

23. The display of claim 17, wherein the low-index epitaxial layer is AlInN.

24. The display of claim 17, wherein the low-index epitaxial layer has an index less than 2.4, at a wavelength of emission of the light-emitting layer.

25. The display of claim 17, wherein the light impinges on the low-index epitaxial layer from a layer that is either GaN or InGaN.

26. The display of claim 17, wherein at least 20% of light emitted by the light-emitting layer is emitted as a total internal reflection (TIR) light, wherein the TIR light is emitted at angles that undergo TIR on the low-index epitaxial layer.

27. A display, comprising:
a semiconductor member having a display output surface to emit a display light in a substantially vertical direction;
a plurality of micro-light emitting diodes (micro-LEDs) formed epitaxially on the semiconductor member, at least one micro-LED comprising:
a light-emitting region;
a mirror formed on a facet of the micro-LED opposite the semiconductor member; and
a low-index epitaxial layer located in the micro-LED or in the semiconductor member,
wherein the low-index epitaxial layer and the mirror are configured such that at least 5% of the light emitted by the light-emitting region undergoes one reflection off the mirror and one total internal reflection off the low-index epitaxial layer before being extracted from the display.

28. The display of claim 27, wherein the at least one micro-LED further comprises non-vertical sidewalls.

29. A display, comprising:
a semiconductor member with a first side comprising a micro-light emitting diode (micro-LED) mesa and a second side opposite the first side comprising a secondary micro-optic,
wherein the micro-LED mesa comprises a non-vertical sidewall and a light- emitting layer configured to emit an emitted light, wherein at least 10% of the emitted light is in a trajectory which impinges on the non-vertical sidewall and then on the secondary micro-optic, and
the non-vertical sidewall and the secondary micro-optic are configured such that light emitted in the trajectory is extracted from the display.

30. The display of claim 29, further comprising:
an optical isolation structure configured to prevent the emitted light from propagating laterally across the display.

31. The display of claim 30, wherein the optical isolation structure is configured such that less than 10% of the emitted light travels laterally more than 10 um from the micro-LED mesa.

32. The display of claim 30, wherein the optical isolation structure is configured such that less than 5% of the emitted light is extracted from the display at a lateral distance more than 10 um from the micro-LED mesa.

33. The display of claim 29, wherein the mesa comprises a mirror in optical proximity to the light-emitting layer, and the mirror and the light-emitting layer are separated by an optical distance based on a predetermined direction corresponding to the trajectory.

34. (canceled)

35. (canceled)

36. (canceled)

37. (canceled)

38. (canceled)

39. (canceled)

40. (canceled)

41. (canceled)

42. (canceled)
